(19) United States
(12) Patent Application Publication
(10) Pub. No.: US 2019/0030651 A1
(43) Pub. Date: Jan. 31, 2019

(54) WAFER PRODUCING METHOD AND WAFER PRODUCING APPARATUS

(71) Applicant: DISCO CORPORATION, Tokyo (JP)

(72) Inventor: Kazuma Sekiya, Tokyo (JP)

(21) Appl. No.: 16/039,626

(22) Filed: Jul. 19, 2018

(30) Foreign Application Priority Data
Jul. 25, 2017 (JP) 2017-143841

(51) Int. Cl. B23K 26/53; B23K 26/00; B23K 26/352

(52) U.S. Cl. CPC B23K 26/53; B23K 26/0006; H01L 23/544; H01L 2223/54433; B23K 26/352

(57) ABSTRACT

A wafer producing method produces a wafer from a semiconductor ingot. The method includes setting the focal point of a first laser beam having a transmission wavelength to the ingot inside the ingot at a predetermined depth from the upper surface of the ingot after flattening the upper surface of the ingot, the predetermined depth corresponding to the thickness of the wafer to be produced, and next applying the first laser beam to the ingot to thereby form a separation layer for separating the wafer from the ingot. The focal point of a second laser beam having a transmission wavelength to the ingot inside the wafer to be produced is set in an area where no devices are to be formed, and the second laser beam is applied to the ingot to thereby form a production history for the wafer inside the ingot.

### BACKGROUND OF THE INVENTION

### Field of the Invention

The present invention relates to a wafer producing method and apparatus for producing a wafer from a semiconductor ingot.

### Description of the Related Art

Various devices such as integrated circuits (ICs), large scale integrated circuits (LSIs), and light emitting diodes (LEDs) are formed by forming a functional layer on the front side of a wafer formed of Si (silicon) or Al₂O₃ (sapphire) and partitioning this functional layer into a plurality of separate regions along a plurality of division lines. Further, power devices or optical devices such as LEDs are formed by forming a functional layer on the front side of a wafer formed of single crystal SiC (silicon carbide) and partitioning this functional layer into a plurality of separate regions along a plurality of division lines. The division lines of such a wafer having these devices are processed by a processing apparatus such as a cutting apparatus and a laser processing apparatus to thereby divide the wafer into a plurality of individual device chips each corresponding to the devices. The device chips thus obtained are used in various electrical equipment such as mobile phones and personal computers.

In general, the wafer on which the devices are to be formed is produced by slicing a cylindrical semiconductor ingot with a wire saw. Both sides of the wafer sliced from the ingot are polished to a mirror finish (see Japanese Patent Laid-open No. 2000-94221, for example).

### SUMMARY OF THE INVENTION

However, the history of the wafer produced from the semiconductor ingot is not always clear. Accordingly, in the case that a defect is caused in any device formed on the wafer in a subsequent step of forming devices on the wafer, the cause of this defect in the device cannot be investigated as following the history of the wafer. This problem may arise regardless of the method of producing the wafer from the ingot. That is, as the method of producing the wafer from the ingot, a method using a wire saw or an inner saw is known. In addition, a method using a laser beam is also known. This method includes the steps of setting the focal point of a laser beam having a transmission wavelength to the ingot inside the ingot, next applying the laser beam to the ingot to thereby form a separation layer at a predetermined depth from the upper surface of the ingot, and next separating a wafer from the ingot along the separation layer as a separation start point to thereby produce the wafer from the ingot. In any of these methods, there is a possibility that the above problem may arise.

It is therefore an object of the present invention to provide a wafer producing method and apparatus which can leave the history of a wafer inside the wafer.

In accordance with an aspect of the present invention, there is provided a wafer producing method for producing a wafer from a semiconductor ingot, the wafer producing method including a production history forming step of setting a focal point of a laser beam having a transmission wavelength to the ingot inside the wafer to be produced in an area where no devices are to be formed, and next applying the laser beam to the ingot to thereby form a production history for the wafer.

In accordance with another aspect of the present invention, there is provided a wafer producing method for producing a wafer from a semiconductor ingot, the wafer producing method including a flattening step of flattening an upper surface of the ingot; a separation layer forming step of setting a focal point of a first laser beam having a transmission wavelength to the ingot inside the ingot at a predetermined depth from the upper surface of the ingot after performing the flattening step, the predetermined depth corresponding to a thickness of the wafer to be produced, and next applying the first laser beam to the ingot to thereby form a separation layer for separating the wafer from the ingot; a production history forming step of setting the focal point of a second laser beam having a transmission wavelength to the ingot inside the wafer to be produced in an area where no devices are to be formed, and next applying the second laser beam to the ingot to thereby form a production history for the wafer inside the ingot; and a wafer producing step of separating the wafer from the ingot along the separation layer as a separation start point after performing the separation layer forming step and the production history forming step, thereby producing the wafer from the ingot.

Preferably, the production history to be formed in the production history forming step includes any one of a lot number of the ingot, a serial number of the wafer to be produced, a date of production of the wafer, a production plant where the wafer is to be produced, and a kind of a wafer producing apparatus contributing to the production of the wafer.

Preferably, the semiconductor ingot includes a single crystal SiC ingot having a first surface, a second surface opposite to the first surface, a c-axis extending from the first surface to the second surface, and a c-plane perpendicular to the c-axis, the c-axis being inclined by an off angle with respect to a normal to the first surface, the off angle being formed between the c-plane and the first surface; the separation layer forming step including a modified layer forming step of setting the focal point of a pulsed laser beam having a transmission wavelength to the SiC ingot inside the SiC ingot at a predetermined depth from the first surface, the predetermined depth corresponding to the thickness of the wafer to be produced, and next applying the pulsed laser beam to the SiC ingot as relatively moving the SiC ingot and the focal point in a first direction perpendicular to a second direction where the off angle is formed, thereby forming a linear modified layer inside the SiC ingot at the predetermined depth so as to extend in the first direction and cracks extending from the modified layer in opposite directions along the c-plane, the modified layer being formed in such a manner that SiC is decomposed into Si and C by the pulsed laser beam first applied, and the pulsed laser beam next applied is absorbed by C previously produced to continue the decomposition of SiC into Si and C in a chain reaction manner with the relative movement of the SiC ingot and the focal point in the first direction; and an indexing step of relatively moving the SiC ingot and the focal point in the second direction by a predetermined index amount; the modified layer forming step and the indexing step being alternately repeated plural times to thereby form the separation layer inside the SiC ingot in the condition where a plurality of linear modified layers are arranged at given intervals in the second direction so as to be connected through the cracks.

In accordance with a further aspect of the present invention, there is provided a wafer producing apparatus for producing a wafer from a semiconductor ingot, the wafer producing apparatus including a chuck table for holding the ingot; a flattening unit for grinding an upper surface of the ingot held on the chuck table to thereby flatten the upper surface of the ingot; a separation layer forming unit for setting a focal point of a first laser beam having a transmission wavelength to the ingot inside the ingot at a predetermined depth from the upper surface of the ingot, the predetermined depth corresponding to a thickness of the wafer to be produced, and next applying the first laser beam to the ingot to thereby form a separation layer for separating the wafer from the ingot; a production history forming unit for setting a focal point of a second laser beam having a transmission wavelength to the ingot inside the wafer to be produced in an area where no devices are to be formed, and next applying the second laser beam to the ingot to thereby form a production history for the wafer inside the ingot; a wafer separating unit for separating the wafer having the production history from the ingot along the separation layer as a separation start point to thereby produce the wafer from the ingot; and a wafer storing unit for storing the wafer separated from the ingot by the wafer separating unit.

According to the present invention, the history of the wafer separated from the semiconductor ingot is formed inside the wafer to be produced. Accordingly, in a subsequent step of forming devices on the wafer, the history of the wafer can be checked. In the case that a defect in any device formed on the wafer is found, the cause of this defect in the device can be investigated by referring to the history formed in the wafer. Accordingly, the recurrence of the defect can be prevented.

The above and other objects, features, and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a wafer producing apparatus according to a preferred embodiment of the present invention;

FIG. 2 is a perspective view of an essential part of the wafer producing apparatus shown in FIG. 1;

FIG. 3 is an enlarged perspective view of an essential part of a flattening unit shown in FIG. 2;

FIG. 4 is a schematic view showing the operation of a cleaning unit shown in FIG. 2, in which a cleaning water is discharged from a first cleaning portion and a dry air is discharged from a second cleaning portion;

FIG. 5 is a perspective view of a laser applying unit shown in FIG. 1;

FIG. 6 is a view similar to FIG. 5, showing a condition where a frame member is removed from the laser applying unit;

FIG. 7 is a block diagram of the laser applying unit shown in FIG. 5;

FIG. 8 is a perspective view of a wafer separating unit shown in FIG. 1;

FIG. 9 is a sectional view of the wafer separating unit shown in FIG. 1;

FIG. 10 is a perspective view of an ingot transfer unit shown in FIG. 1;

FIG. 11A is an elevational view of a semiconductor ingot;

FIG. 11B is a plan view of the ingot shown in FIG. 11A;

FIG. 12A is a perspective view of the ingot and a substrate to be mounted thereon;

FIG. 12B is a view similar to FIG. 12A, showing a condition where the substrate is mounted on the ingot;

FIG. 13 is a perspective view showing a holding step;

FIG. 14 is a plan view showing a condition where a first ingot is set at a flattening position and a second ingot is set at a standby position;

FIG. 15 is a plan view showing a condition where the first ingot is set at a laser applying position, the second ingot is set at the flattening position, and a third ingot is set at the standby position;

FIG. 16A is a perspective view showing a separation layer forming step;

FIG. 16B is an elevational view showing the separation layer forming step shown in FIG. 16A;

FIG. 17A is a plan view of the ingot in which a separation layer has been formed in the separation layer forming step;

FIG. 17B is a cross section taken along the line B-B in FIG. 17A;

FIG. 18A is a perspective view showing a production history forming step;

FIG. 18B is an elevational view showing the production history forming step shown in FIG. 18A;

FIG. 19 is a plan view showing a condition where the first ingot is set at a wafer separating position, the second ingot is set at the laser applying position, the third ingot is set at the flattening position, and a fourth ingot is set at the standby position;

FIG. 20A is a perspective view showing a condition where a liquid tank is positioned directly above a chuck table in a wafer producing step;

FIG. 20B is a view similar to FIG. 20A, showing a condition where the lower surface of the liquid tank is in contact with the upper surface of the chuck table in the wafer producing step;

FIG. 21 is a perspective view showing a condition where a wafer has been separated from the ingot by the wafer separating unit;

FIG. 22 is a plan view showing a condition where the first ingot is set at the standby position, the second ingot is set at the wafer separating position, the third ingot is set at the laser applying position, and the fourth ingot is set at the flattening position;

FIG. 23 is a plan view showing a condition where the first ingot is set at the flattening position, the second ingot is set at the standby position, the third ingot is set at the wafer separating position, and the fourth ingot is set at the laser applying position; and

FIG. 24 is a plan view showing a condition where the first ingot is set at the laser applying position, the second ingot is set at the flattening position, the third ingot is set at the standby position, and the fourth ingot is set at the wafer separating position.

### DETAILED DESCRIPTION OF THE PREFERRED EMBODIMENT

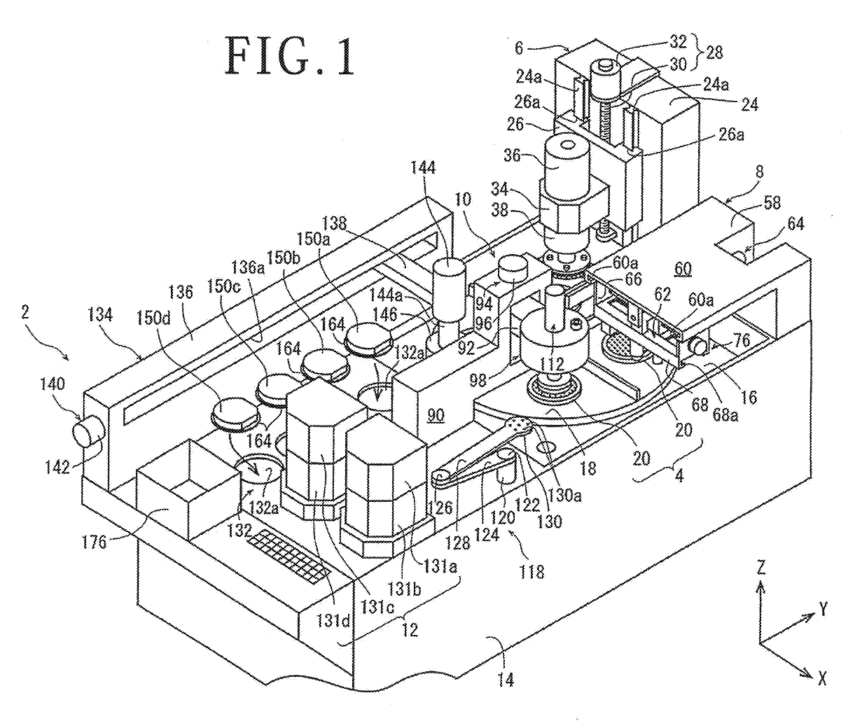

A preferred embodiment of the wafer producing method and the wafer producing apparatus according to the present invention will now be described with reference to the drawings. FIG. 1 shows a wafer producing apparatus 2 according to this preferred embodiment. The wafer producing apparatus 2 includes: a holding unit 4 for holding a semiconductor ingot, a flattening unit 6 for grinding the upper surface of the ingot held by the holding unit 4, thereby flattening the upper surface of the ingot; a separation layer forming unit for setting the focal point of a first laser beam having a transmission wavelength to the ingot inside the ingot at a predetermined depth from the upper surface of the ingot held by the holding unit 4, the predetermined depth corresponding to the thickness of a wafer to be produced, and next applying the first laser beam to the ingot to thereby form a separation layer for separating the wafer from the ingot; a production history forming unit for setting the focal point of a second laser beam having a transmission wavelength to the ingot inside the wafer to be produced in an area where no devices are to be formed, and next applying the second laser beam to the ingot to thereby form a production history for the wafer inside the ingot; a wafer separating unit 10 for holding the upper surface of the ingot to separate the wafer from the ingot along the separation layer; and a wafer storing unit 12 for storing the wafer separated from the ingot. In this preferred embodiment, the separation layer forming unit and the production history forming unit are provided by a common laser applying unit 8. As a modification, the separation layer forming unit and the production history forming unit may be provided by separate laser applying units.

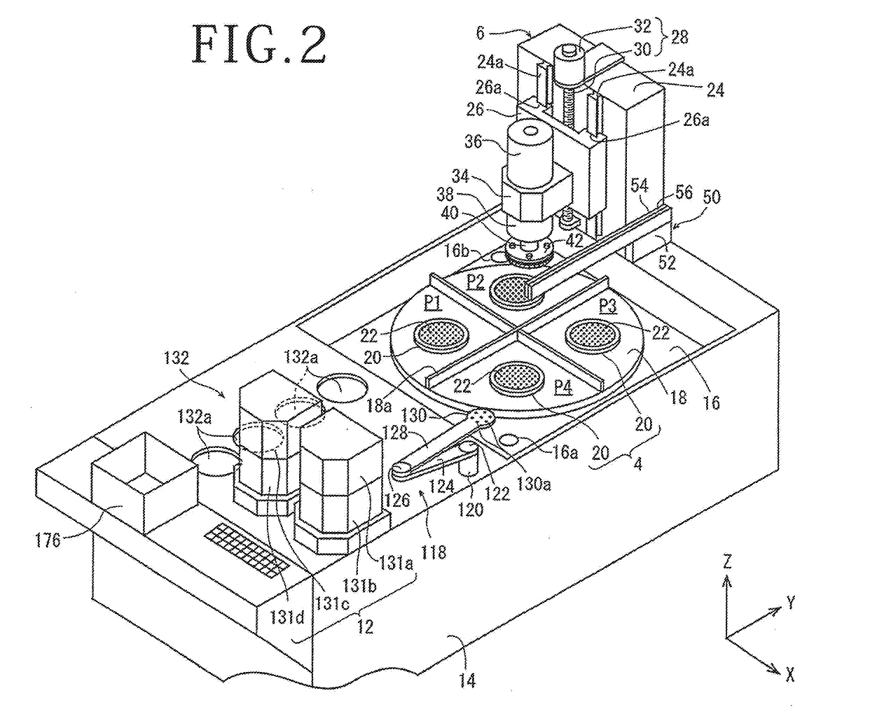

The holding unit 4 will now be described with reference to FIG. 2. The wafer producing apparatus 2 includes a base 14 having an upper surface. The upper surface of the base 14 is recessed to form a turn table accommodating portion 16 having a rectangular shape as viewed in plan. A circular turn table 18 is accommodated in the turn table accommodating portion 16. The turn table 18 is adapted to be rotated by a turn table motor (not shown) built in the base 14. The turn table 18 is rotatable about its axis extending in the Z direction through the radial center of the turn table 18. The holding unit 4 is composed of four circular chuck tables 20 rotatably provided on the upper surface of the turn table 18. As shown in FIG. 2, by the rotation of the turn table 18, each chuck table 20 is adapted to take a standby position P1, a flattening position P2 below the flattening unit 6, a laser applying position P3 below the laser applying unit 8, and a wafer separating position P4 below the wafer separating unit 10. The four chuck tables 20 are adapted to be rotated by four chuck table motors (not shown) built in the base 14. Each chuck table 20 is rotatable about its axis extending in the Z direction through the radial center of each chuck table 20.

The four chuck tables 20 are arranged at equal intervals in the circumferential direction of the turn table 18 (i.e., at intervals of 90 degrees), and partitioned by a crossing partition wall 18a provided on the upper surface of the turn table 18. The upper surface of each chuck table 20 is provided with a circular vacuum chuck 22 formed of a porous material. The vacuum chuck 22 has an upper surface present in a substantially horizontal plane. The vacuum chuck 22 of each chuck table 20 is connected through a suction passage to a suction unit (not shown). Accordingly, a suction force generated by the suction unit is adapted to be applied to the upper surface of the vacuum chuck 22 in each chuck table 20 constituting the holding unit 4, so that the ingot placed on the upper surface of the vacuum chuck 22 can be held under suction. The Z direction is a vertical direction shown by an arrow Z in FIG. 2. Further, the X direction shown by an arrow X in FIG. 2 is a direction perpendicular to the Z direction, and the Y direction shown by an arrow Y in FIG. 2 is a direction perpendicular to both the X direction and the Z direction. The XY plane defined by the X direction and the Y direction is a substantially horizontal plane.

As shown in FIG. 2, the flattening unit 6 includes a rectangular mounting wall 24 extending in the Z direction from the upper surface of the base 14 at one end thereof in the Y direction, a rectangular Z movable plate 26 mounted on the mounting wall 24 so as to be movable in the Z direction, and a Z moving mechanism 28 for moving the Z movable plate 26 in the Z direction. A pair of guide rails 24a extending in the Z direction are provided on one side of the mounting wall 24 (i.e., on the front side in the Y direction in FIG. 2). The guide rails 24a are spaced from each other in the X direction. As corresponding to the guide rails 24a of the mounting wall 24, a pair of guided rails 26a extending in the Z direction are formed on the Z movable plate 26. The guided rails 26a of the Z movable plate 26 are slidably engaged with the guide rails 24a of the mounting wall 24, so that the Z movable plate 26 is mounted on the mounting wall 24 so as to be movable in the Z direction. The Z moving mechanism 28 has a ball screw 30 extending in the Z direction along one side of the mounting wall 24 and a motor 32 connected to one end of the ball screw 30. The ball screw 30 has a nut portion (not shown), which is fixed to the Z movable plate 26. Accordingly, the rotary motion of the motor 32 is converted into a linear motion by the ball screw 30, and this linear motion is transmitted to the Z movable plate 26, so that the Z movable plate 26 can be moved in the Z direction along the guide rails 24a of the mounting wall 24.

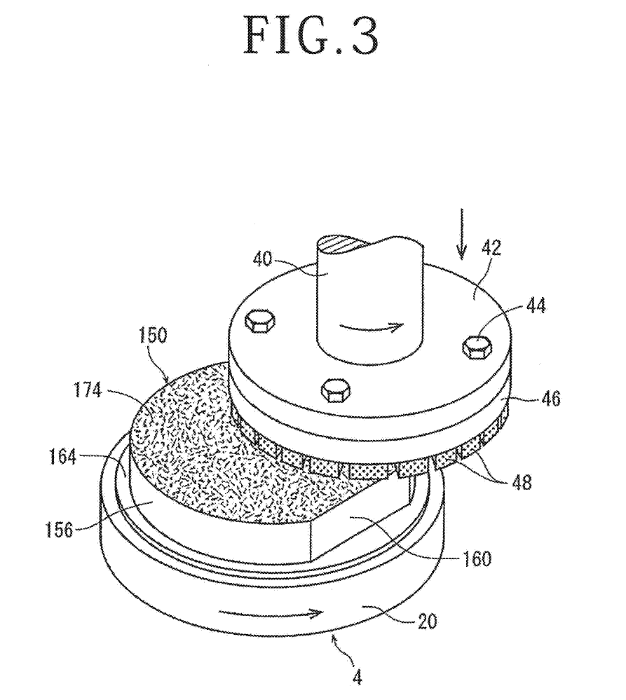

The flattening unit 6 will further be described with reference to FIGS. 2 and 3. A support block 34 is fixed to the front side of the Z movable plate 26 so as to project in the Y direction. A motor 36 is supported on the upper surface of the support block 34, and a hollow cylindrical spindle housing 38 is supported on the lower surface of the support block 34 so as to extend downward. A solid cylindrical spindle 40 is supported to the spindle housing 38 so as to be rotatable about a vertical axis extending in the Z direction. The upper end of the spindle 40 is connected to the motor 36, so that the spindle 40 can be rotated about its axis by operating the motor 36. As shown in FIG. 3, a disk-shaped wheel mount 42 is fixed to the lower end of the spindle 40. An annular grinding wheel 46 is fixed to the lower surface of the wheel mount 42 by bolts 44. A plurality of abrasive members 48 are fixed to the lower surface of the grinding wheel 46 so as to be annularly arranged at given intervals along the outer circumference of the grinding wheel 46. As shown in FIG. 3, when the chuck table 20 is set at the flattening position P2, the center of rotation of the grinding wheel 46 is deviated from the center of rotation of the chuck table 20 in such a manner that a ring formed by the plural abrasive members 48 passes through the center of the chuck table 20 as viewed in plan. Accordingly, when both the chuck table 20 and the grinding wheel 46 are rotated and the abrasive members 48 come into contact with the upper surface of the ingot held on the chuck table 20, the whole of the upper surface of the ingot can be ground by the abrasive members 48 in the flattening unit 6. Thus, the upper surface of the ingot held on the chuck table 20 can be uniformly ground to be flattened.

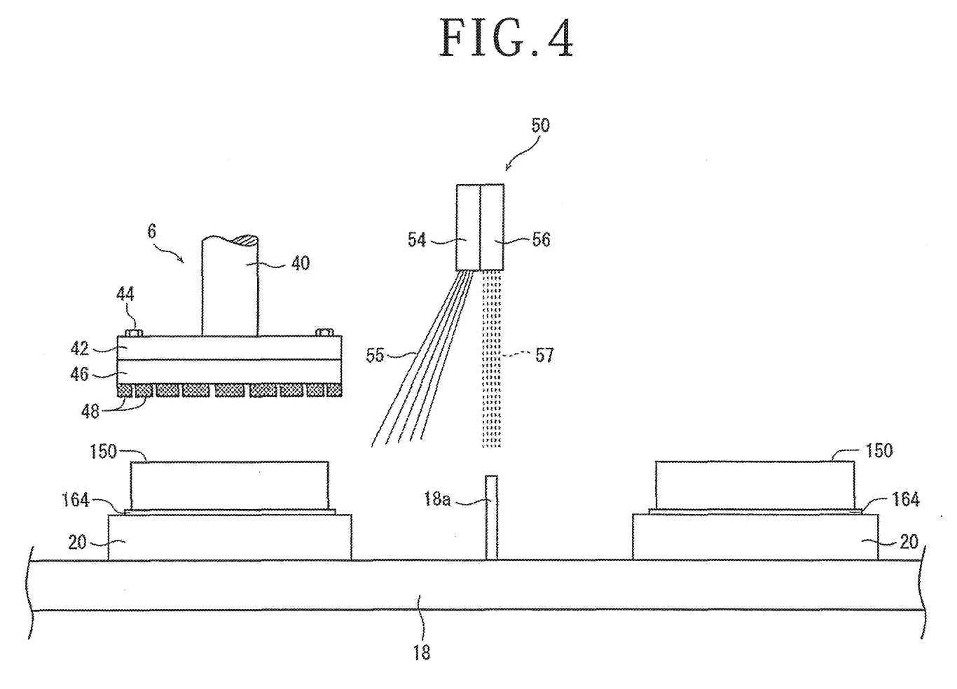

Preferably, the wafer producing apparatus 2 includes a cleaning unit 50 for cleaning the ingot whose upper surface has been flattened by the flattening unit 6. As shown in FIG. 2, the cleaning unit 50 includes: a support member 52 mounted on the upper surface of the base 14 along the side surface of the mounting wall 24 of the flattening unit 6; a first cleaning portion 54 extending from the upper end of the support member 52 in the Y direction; and a second cleaning portion 56 extending from the upper end of the support member 52 in the Y direction so as to be juxtaposed to the first cleaning portion 54 in the Y direction. The first cleaning portion 54 may be formed from a hollow member, and a plurality of nozzle holes (not shown) are formed on the lower surface of the first cleaning portion 54 so as to be spaced in the Y direction. The plural nozzle holes of the first cleaning portion 54 are connected through a fluid passage to a cleaning water supply unit (not shown). Similarly, the second cleaning portion 56 may be formed from a hollow member, and a plurality of nozzle holes (not shown) are formed on the lower surface of the second cleaning portion 56 so as to be spaced in the Y direction. The plural nozzle holes of the second cleaning portion 56 are connected through a fluid passage to a dry air source (not shown). As shown in FIG. 4, the cleaning unit 50 is operated in such a manner that a cleaning water 55 is discharged obliquely downward from each nozzle hole of the first cleaning portion 54 toward the ingot held on the chuck table 20 set below the flattening unit 6, thereby removing a grinding dust from the ingot. Thus, the ingot flattened by the flattening unit 6 can be cleaned by the cleaning water 55. Further, a dry air 57 is discharged downward from each nozzle hole of the second cleaning portion 56, thereby removing the cleaning water 55 from the ingot. Thus, the ingot cleaned by the cleaning water 55 can be dried by the dry air 57.

The laser applying unit 8 functioning both as the separation layer forming unit and as the production history forming unit will now be described with reference to FIGS. 1, 5, and 6. The laser applying unit 8 includes a frame member 58 extending upward from the upper surface of the base 14 so as to be located adjacent to the mounting wall 24 of the flattening unit 6 in the X direction, a rectangular guide plate 60 extending from the upper end of the frame member 58 in the Y direction, a Y movable member 62 supported to the guide plate 60 so as to be movable in the Y direction, and a Y moving mechanism 64 for moving the Y movable member 62 in the Y direction. A pair of guide rails 60a extending in the Y direction are formed on the lower surface of the guide plate 60 at its opposite ends in the X direction. As shown in FIG. 6, the Y movable member 62 has a pair of guided portions 66 spaced in the X direction and a mounting portion 68 extending in the X direction so as to connect the lower ends of the guided portions 66. A guided rail 66a extending in the Y direction is formed at the upper end of each guided portion 66. The guided rails 66a of the guided portion 66 are slidably engaged with the guide rails 60a of the guide plate 60, so that the Y movable member 62 is supported to the guide plate 60 so as to be movable in the Y direction. Further, a pair of guide rails 68a extending in the X direction are formed on the lower surface of the mounting portion 68 at its opposite ends in the Y direction. As shown in FIG. 6, the Y moving mechanism 64 has a ball screw 70 extending in the Y direction so as to be located below the guide plate 60 and a motor 72 connected to one end of the ball screw 70. The ball screw 70 has an inverted U-shaped nut portion 70a, which is fixed to the upper surface of the mounting portion 68. Accordingly, the rotary motion of the motor 72 can be converted into a linear motion by the ball screw 70, and this linear motion can be transmitted to the Y movable member 62. As a result, the Y movable member 62 can be moved in the Y direction along the guide rails 60a of the guide plate 60 by operating the Y moving mechanism 64.

The laser applying unit 8 will further be described with reference to FIG. 6. The laser applying unit 8 further includes an X movable plate 74 mounted on the mounting portion 68 of the Y movable member 62 so as to be movable in the X direction, and an X moving mechanism 76 for moving the X movable plate 74 in the X direction. The opposite ends of the X movable plate 74 in the Y direction are slidably engaged with the guide rails 68a of the mounting portion 68, so that the X movable plate 74 is mounted on the mounting portion 68 so as to be movable in the X direction. The X moving mechanism 76 has a ball screw 78 extending in the X direction so as to be located above the mounting portion 68 and a motor 80 connected to one end of the ball screw 78. The ball screw 78 has a nut portion 78a, which is fixed to the upper surface of the X movable plate 74. The mounting portion 68 has an elongated opening 68b in which the nut portion 78a is movable in the X direction. Accordingly, the rotary motion of the motor 80 can be converted into a linear motion by the ball screw 78, and this linear motion can be transmitted to the X movable plate 74. As a result, the X movable plate 74 can be moved in the X direction along the guide rails 68a of the mounting portion 68 by operating the X moving mechanism 76.

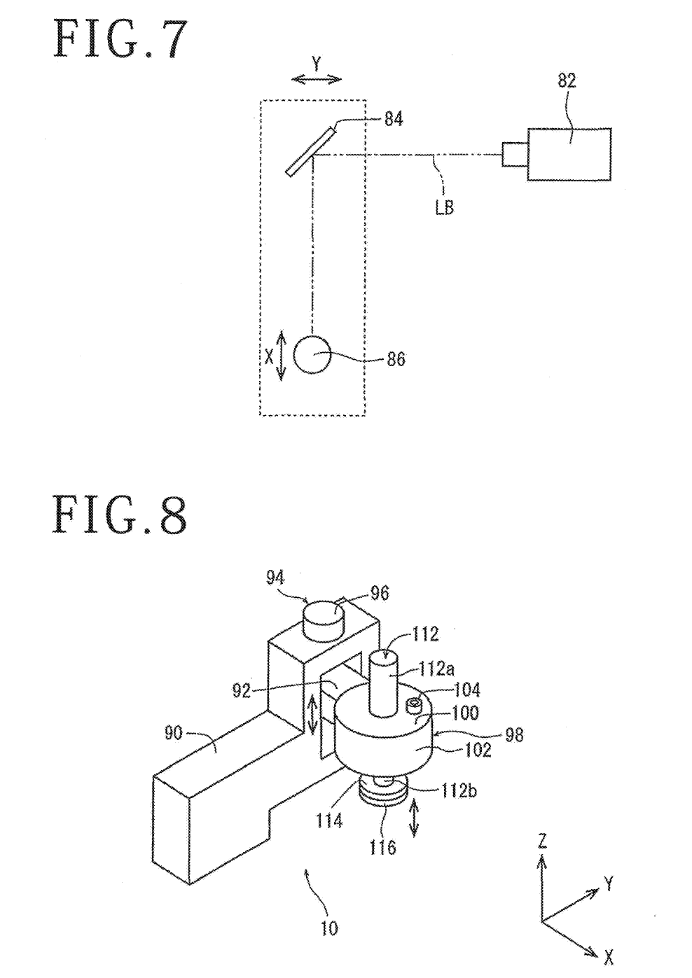

The laser applying unit 8 will further be described with reference to FIGS. 6 and 7. The laser applying unit 8 further includes a laser oscillator 82 built in the frame member 58, an attenuator (not shown) for adjusting the power of a pulsed laser beam LB oscillated by the laser oscillator 82, a first mirror 84 mounted on the lower surface of the mounting portion 68 of the Y movable member 62 so as to be spaced from the laser oscillator 82 in the Y direction, focusing means 86 mounted on the lower surface of the X movable plate 74 so as to be movable in the Z direction, a second mirror (not shown) mounted on the lower surface of the X movable plate 74 so as to be located directly above the focusing means 86 and be spaced from the first mirror 84 in the X direction, whereby the pulsed laser beam LB reflected by the first mirror 84 is guided to the focusing means 86 by the second mirror, an alignment unit 88 mounted on the lower surface of the X movable plate 74 so as to be spaced from the focusing means 86 in the X direction, and a focal position adjusting unit (not shown) for moving the focusing means 86 in the Z direction to adjust the Z position of the focal point of the focusing means 86, that is, the vertical position of the focal point of the pulsed laser beam LB to be applied to the ingot.

The laser oscillator 82 functions to oscillate a pulsed laser beam LB having a transmission wavelength to the ingot. The focusing means 86 has a focusing lens (not shown) for focusing the pulsed laser beam LB oscillated from the laser oscillator 82. The focusing lens is located below the second mirror. The alignment unit 88 functions to image the ingot held on the chuck table 20 and detect an area to be laser-processed. The focal position adjusting unit may be so configured as to have a ball screw (not shown) extending in the Z direction and a motor (not shown) connected to one end of the ball screw, and the ball screw had a nut portion fixed to the focusing means 86. The focal position adjusting unit is operated in such a manner that the rotary motion of the motor is converted into a linear motion by the ball screw, and this linear motion is transmitted to the focusing means 86. Accordingly, the focusing means 86 can be moved in the Z direction along a guide rail (not shown), so that the Z position of the focal point of the pulsed laser beam LB to be focused by the focusing means can be adjusted. The optical path of the pulsed laser beam LB to be oscillated from the laser oscillator 82 is set to extend in the Y direction. The power of the pulsed laser beam LB oscillated from the laser oscillator 82 is adjusted to a suitable power by the attenuator. The first mirror 84 functions to change the optical path (traveling direction) of the pulsed laser beam LB oscillated from the laser oscillator 82 from the Y direction to the X direction. The second mirror functions to change the optical path (traveling direction) of the pulsed laser beam LB reflected by the first mirror 84 from the X direction to the Z direction, thereby guiding the pulsed laser beam LB to the focusing lens of the focusing means 86. The pulsed laser beam LB thus guided to the focusing lens is focused by the focusing lens of the focusing means 86 and applied to the ingot held on the chuck table 20.

Even when the focusing means 86 is moved in the Y direction by operating the Y moving mechanism 64 to move the Y movable member 62 or the focusing means 86 is moved in the X direction by operating the X moving mechanism 76 to move the X movable plate 74, the optical path of the pulsed laser beam LB oscillated from the laser oscillator 82 is changed from the Y direction to the X direction by the first mirror 84 and guided to the second mirror. Thereafter, the optical path of the pulsed laser beam LB guided to the second mirror is changed from the X direction to the Z direction by the second mirror and guided to the focusing means 86. In the laser applying unit 8 configured above, a separation layer can be formed inside the ingot and a production history can also be formed inside the ingot (more specifically, inside the wafer to be produced) by applying the pulsed laser beam LB to the ingot in the following manner. First, the ingot held on the chuck table 20 is imaged by the alignment unit 88 to detect an area to be laser-processed. Thereafter, the focusing means 86 is moved in the Z direction by operating the focal position adjusting unit to set the focal point of the pulsed laser beam LB having a transmission wavelength to the ingot inside the ingot at a predetermined depth from the upper surface of the ingot held on the chuck table 20, the predetermined depth corresponding to the thickness of the wafer to be produced. Thereafter, the pulsed laser beam LB is applied from the focusing means 86 to the ingot held on the chuck table 20 as suitably moving the X movable plate 74 in the X direction by operating the X moving mechanism 76 and also suitably moving the Y movable member 62 in the Y direction by operating the Y moving mechanism 64.

The wafer separating unit 10 will now be described with reference to FIGS. 1 and 8. The wafer separating unit 10 includes a support member 90 fixed to the upper surface of the base 14, an arm 92 having a base end supported to the support member 90 so as to be movable in the Z direction, the arm 92 extending from the base end in the X direction, and an arm moving mechanism 94 for moving the arm 92 in the Z direction. The arm moving mechanism 94 has a ball screw (not shown) extending in the Z direction so as to be located in the support member 90 and a motor 96 connected to one end of this ball screw. The ball screw of the arm moving mechanism 94 has a nut portion (not shown), which is fixed to the base end of the arm 92. Accordingly, the rotary motion of the motor 96 can be converted into a linear motion by the ball screw, and this linear motion can be transmitted to the arm 92. As a result, the arm 92 can be moved in the Z direction by the arm moving mechanism 94 along a guide rail (not shown) built in the support member 90 so as to extend in the Z direction.

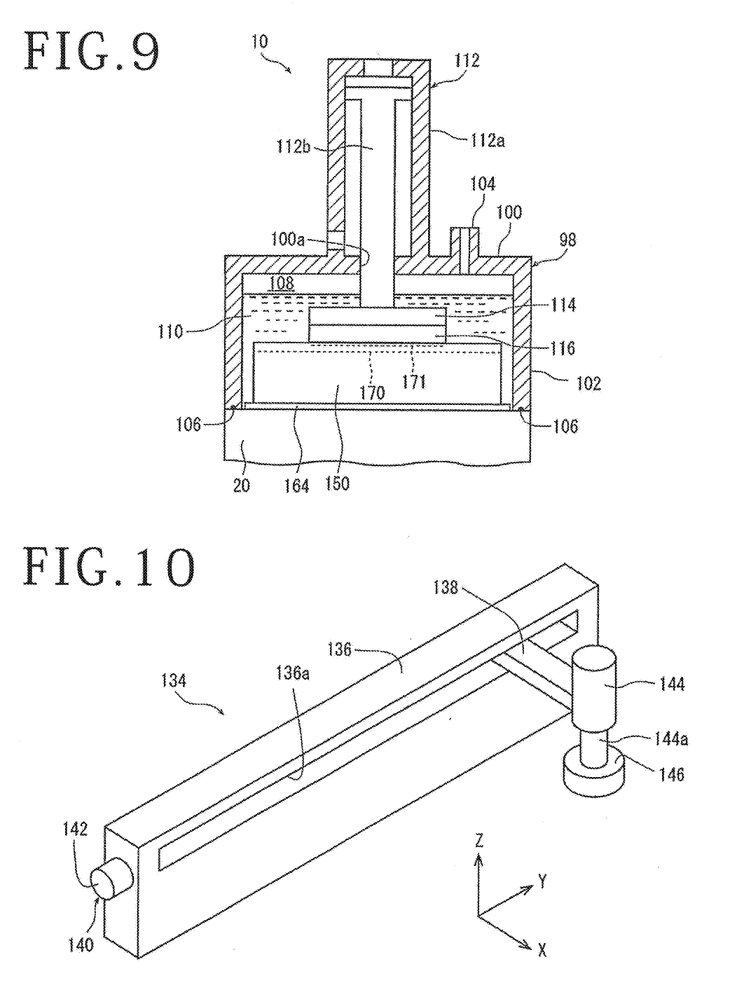

The wafer separating unit 10 will further be described with reference to FIGS. 8 and 9. A liquid tank 98 is fixed to the front end of the arm 92. The liquid tank 98 functions to store a liquid in cooperation with the chuck table 20 in separating the wafer from the ingot. The liquid tank 98 has a circular top wall 100 and a cylindrical side wall 102 extending downward from the outer circumference of the top wall 100. That is, the bottom of the liquid tank 98 is open. The outer diameter of the side wall 102 is equal to or less than the diameter of the chuck table 20, so that when the arm 92 is lowered, the lower end of the side wall 102 comes into contact with the upper surface of the chuck table 20. The top wall 100 is formed with a cylindrical liquid inlet portion 104 communicating with the inside of the liquid tank 98 and the outside thereof. The liquid inlet portion 104 is connected through a fluid passage to a liquid supply unit (not shown). As shown in FIG. 9, an annular gasket 106 is mounted on the lower end of the side wall 102. When the arm 92 is lowered by the arm moving mechanism 94 to bring the lower end of the side wall 102 into close contact with the upper surface of the chuck table 20, a liquid storing space 108 is defined by the upper surface of the chuck table 20 and the inside surface of the liquid tank 98. A liquid 110 is supplied from the liquid supply unit through the liquid inlet portion 104 into the liquid storing space 108. At this time, the leakage of the liquid 110 stored in the liquid storing space 108 is prevented by the gasket 106.

The wafer separating unit 10 will further be described with reference to FIGS. 8 and 9. An air cylinder 112 is mounted on the top wall 100 of the liquid tank 98. The air cylinder 112 includes a cylinder tube 112a and a piston rod 112b. The cylinder tube 112a extends upward from the upper surface of the top wall 100. The piston rod 102b is accommodated in the cylinder tube 112a, and the lower end portion of the piston rod 112b is inserted through an opening 100a of the top wall 100 to project downward from the top wall 100. A disk-shaped ultrasonic vibration generating member 114 is fixed to the lower end of the piston rod 112b. The ultrasonic vibration generating member 114 may be formed of piezoelectric ceramic. A disk-shaped suction member 116 is fixed to the lower end of the ultrasonic vibration generating member 114. The lower surface of the suction member 116 is formed with a plurality of suction holes (not shown), which are connected through a suction passage to a suction unit (not shown). Accordingly, a suction force generated by the suction unit can be applied to the lower surface of the suction member 116, thereby holding the ingot on the lower surface of the suction member 116 under suction. The wafer separating unit 10 configured above is operated in the following manner. The arm 92 is lowered by the arm moving mechanism 94 until the lower end of the side wall 102 comes into close contact with the upper surface of the chuck table 20 holding the ingot in which the separation layer has been formed by the laser applying unit 8. Further, the piston rod 112b of the air cylinder 112 is lowered until the lower surface of the suction member 116 comes into contact with the upper surface of the ingot held on the chuck table 20 to hold the upper surface of the ingot under suction. Thereafter, the liquid 110 is stored into the liquid storing space 108, and the ultrasonic vibration generating member 114 is next operated to apply ultrasonic vibration to the ingot. As a result, the wafer to be produced can be separated from the ingot along the separation layer as a separation start point.

The wafer storing unit 12 will now be described with reference to FIGS. 1 and 2. The wafer storing unit 12 includes at least one cassette capable of storing a plurality of wafers in the condition where these wafers are arranged at given intervals in a vertical direction, and each wafer has been separated from the ingot along the separation layer by the wafer separating unit 10. In the case that the wafer storing unit 12 includes a plurality of such cassettes, these cassettes may be the same. In this preferred embodiment, the wafer storing unit 12 is composed of four cassettes, that is, a first cassette 131a, a second cassette 131b, a third cassette 131c, and a fourth cassette 131d. Further, a wafer transfer unit 118 is provided between the wafer separating unit 10 and the wafer storing unit 12. The wafer transfer unit 118 functions to transfer the wafer from the wafer separating unit 10 to the wafer storing unit 12 after the wafer has been separated from the ingot along the separation layer by the wafer separating unit 10. As shown in FIGS. 1 and 2, the wafer transfer unit 118 includes an elevating unit 120 extending upward from the upper surface of the base 14, a first motor 122 fixed to the upper end of the elevating unit 120, a first arm 124 connected at its base end to the first motor 122 so as to be rotatable about an axis extending in the Z direction, a second motor 126 fixed to the front end of the first arm 124, a second arm 128 connected at its base end to the second motor 126 so as to be rotatable about an axis extending in the Z direction, and a disk-shaped suction member 130 fixed to the front end of the second arm 128.

The first motor 122 is vertically moved in the Z direction by the elevating unit 120. The first arm 124 is rotated by the first motor 122 with respect to the elevating unit 120 about the rotation axis extending through the base end of the first arm 124 in the Z direction. The second arm 128 is rotated by the second motor 126 with respect to the first arm 124 about the rotation axis extending through the base end of the second arm 128 in the Z direction. The upper surface of the suction member 130 is formed with a plurality of suction holes 130a, which are connected through a suction passage to a suction unit (not shown). Accordingly, a suction force generated by the suction unit can be applied to the upper surface of the suction member 130 in the wafer transfer unit 118, so that the wafer separated from the ingot along the separation layer by the wafer separating unit 10 can be held on the upper surface of the suction member 130 under suction. At the same time, the first arm 124 and the second arm 128 are operated by the elevating unit 120, the first motor 122, and the second motor 126, so that the wafer held by the suction member 130 can be transferred from the wafer separating unit 10 to the wafer storing unit 12.

As shown in FIG. 1, the wafer producing apparatus 2 preferably further includes an ingot storing unit 132 for storing the ingot and an ingot transfer unit 134 for transferring the ingot from the ingot storing unit 132 to the holding unit 4. In this preferred embodiment, the ingot storing unit 132 is composed of four circular storing recesses 132a formed on the upper surface of the base 14 so as to be spaced in the Y direction. Each storing recess 132a has a diameter slightly larger than the diameter of the ingot. Accordingly, the ingot can be stored in each storing recess 132a.

The ingot transfer unit 134 will now be described with reference to FIGS. 1 and 10. The ingot transfer unit 134 includes a frame member 136 provided on the upper surface of the base 14 so as to extend in the Y direction along the ingot storing unit 132, an arm 138 supported at its base end to the frame member 136 so as to be movable in the Y direction, the arm 138 extending from the base end in the X direction, and an arm moving mechanism 140 for moving the arm 138 in the Y direction. The frame member 136 is formed with a rectangular guide opening 136a elongated in the Y direction. The arm moving mechanism 140 has a ball screw (not shown) extending in the Y direction so as to be located in the frame member 136 and a motor 142 connected to one end of this ball screw. The ball screw of the arm moving mechanism 140 has a nut portion (not shown), which is fixed to the base end of the arm 138. Accordingly, the rotary motion of the motor 142 can be converted into a linear motion by the ball screw, and this linear motion can be transmitted to the arm 138. As a result, the arm 138 can be moved in the Y direction by the arm moving mechanism 140 along the guide opening 136a of the frame member 136. As shown in FIG. 10, an air cylinder 144 extending in the Z direction is mounted on the front end of the arm 138. The air cylinder 144 has a piston rod 144a projecting downward. A disk-shaped suction member 146 is fixed to the lower end of the piston rod 144a. The lower surface of the suction member 146 is formed with a plurality of suction holes (not shown), which are connected through a suction passage to a suction unit (not shown). Accordingly, a suction force generated by the suction unit can be applied to the lower surface of the suction member 146, so that the upper surface of the ingot stored in the ingot storing unit 132 can be held on the lower surface of the suction member 146 under suction. In this condition, by operating the arm moving mechanism 140 to move the arm 138 in the Y direction and operating the air cylinder 144 to move the suction member 146 in the Z direction, the ingot held by the suction member 146 can be transferred from the ingot storing unit 132 to the holding unit 4.

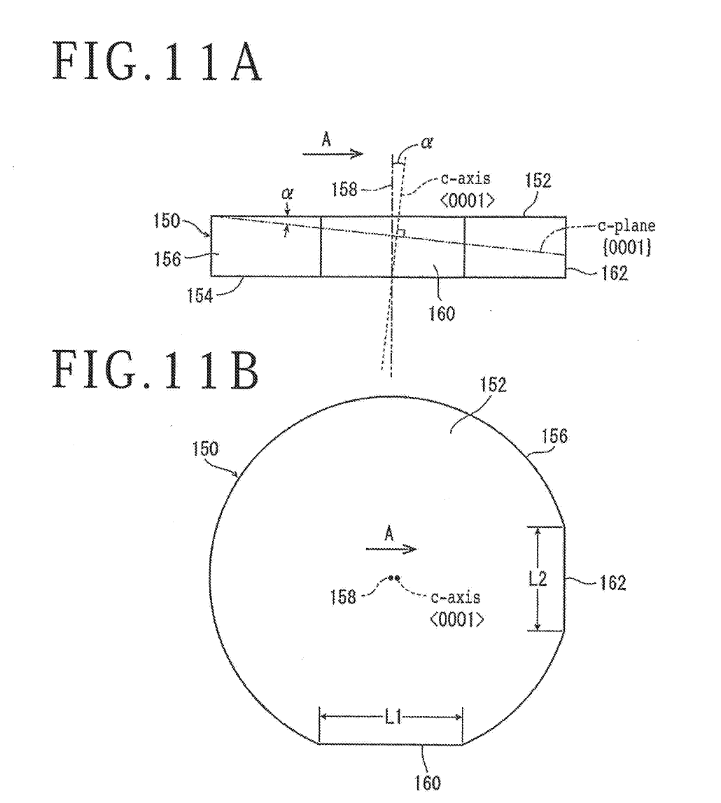

FIGS. 11A and 11B show an ingot 150 to be processed by the wafer producing apparatus 2. The ingot 150 shown in FIGS. 11A and 11B is a substantially cylindrical ingot formed of hexagonal single crystal SiC. The ingot 150 has a substantially circular first surface 152, a substantially circular second surface 154 opposite to the first surface 152, a substantially cylindrical surface 156 formed so as to connect the first surface 152 and the second surface 154, a c-axis (<0001> direction) extending from the first surface 152 to the second surface 154, and a c-plane ({0001} plane) perpendicular to the c-axis. In the ingot 150, the c-axis is inclined by an off angle α (e.g., α=1, 3, or 6 degrees) with respect to a normal 158 to the first surface 152. The off angle α is formed between the c-plane and the first surface 152. The direction of formation of the off angle α (i.e., the direction of inclination of the c-axis) is shown by an arrow A in FIGS. 11A and 11B. Further, the cylindrical surface 156 of the ingot 150 is formed with a first orientation flat 160 and a second orientation flat 162, which are both rectangular in shape as viewed in side elevation. These orientation flats 160 and 162 are formed to indicate crystal orientation. The first orientation flat 160 extends parallel to the direction A of formation of the off angle α, and the second orientation flat 162 extends perpendicular to the direction A of formation of the off angle α. As shown in FIG. 11B, which is a plan view taken in the direction of extension of the normal 158, the length L2 of the second orientation flat 162 is set shorter than the length L1 of the first orientation flat 160 (L2<L1).

The semiconductor ingot to be processed by the wafer producing apparatus 2 is not limited to the hexagonal single crystal SiC ingot 150. For example, the semiconductor ingot to be processed in the present invention may be a single crystal SiC ingot such that the c-axis is not inclined with respect to the normal 158 to the first surface 152, and the off angle α between the c-plane and the first surface 152 is 0 degree (i.e., the c-axis coincides with the normal 158 to the first surface 152). Further, the semiconductor ingot to be processed in the present invention may be a single crystal GaN ingot formed of single crystal GaN (gallium nitride), for example. That is, the material of the semiconductor ingot is not limited to single crystal SiC in the present invention.

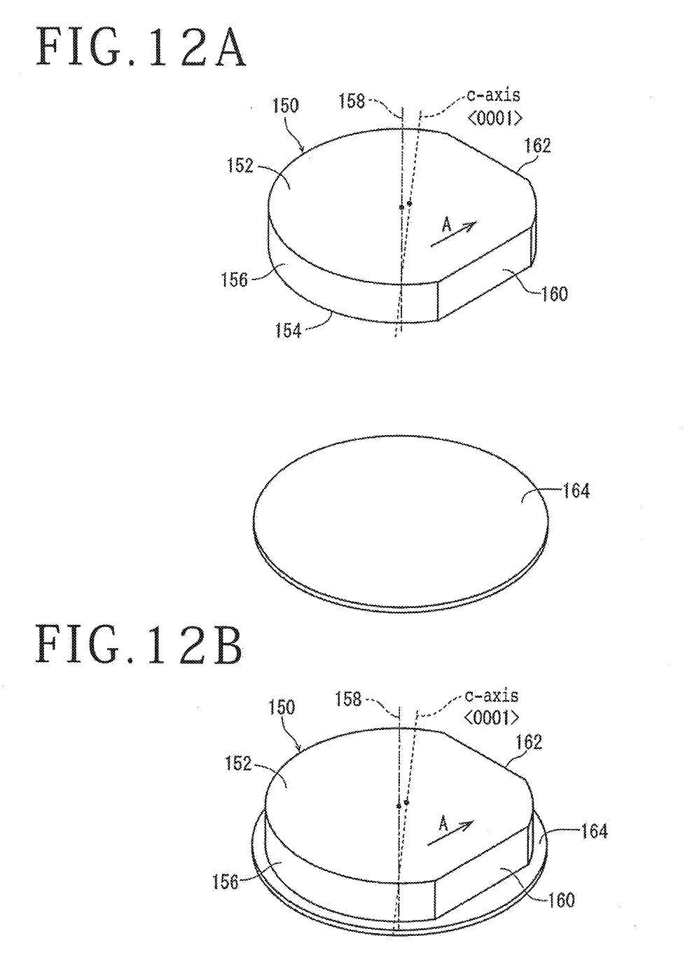

There will now be described a wafer producing method according to the present invention. In this preferred embodiment, the wafer producing method using the wafer producing apparatus 2 mentioned above will be described with reference to the drawings. In the wafer producing method using the wafer producing apparatus 2, four ingots 150 are first prepared. Thereafter, as shown in FIGS. 12A and 12B, a substrate mounting step is performed to mount a disk-shaped substrate 164 on the lower surface of each ingot 150 (e.g., the second surface 154 of each ingot 150) through a suitable adhesive. The substrate mounting step is performed for the purpose of holding each ingot 150 having the first orientation flat 160 and the second orientation flat 162 on the circular vacuum chuck 22 of the chuck table 20 by applying a predetermined suction force. The diameter of the substrate 164 is slightly larger than the diameter of each ingot 150 and slightly larger than the diameter of the vacuum chuck 22 of the chuck table 20. Accordingly, when each ingot 150 is placed on the chuck table 20 in the condition where the substrate 164 is oriented downward, the vacuum chuck 22 is fully covered with the substrate 164, so that when the suction unit connected to the vacuum chuck 22 is operated, the substrate 164 can be held on the vacuum chuck 22 under suction by a predetermined suction force. Accordingly, each ingot 150 having the first orientation flat 160 and the second orientation flat 162 can be held through the substrate 164 on the chuck table 20 under suction. In the case that the diameter of each ingot is larger than that of the vacuum chuck 22, the upper surface of the vacuum chuck 22 is fully covered with each ingot placed on the chuck table 20. In this case, there is no possibility that air may be sucked around each ingot placed on the vacuum chuck 22 in operating the suction unit, so that each ingot can be held on the vacuum chuck 22 under suction by a predetermined suction force. Accordingly, in this case, the substrate mounting step may not be performed.

After performing the substrate mounting step, an ingot storing step is performed to store each ingot 150 into the ingot storing unit 132. In this preferred embodiment shown in FIG. 1, the four ingots 150 each having the substrate 164 are stored into the four storing recesses 132a of the ingot storing unit 132, respectively, in the condition where the substrate 164 is oriented downward. In the following description, the four ingots 150 will be individually defined as a first ingot 150a, a second ingot 150b, a third ingot 150c, and a fourth ingot 150d for convenience of illustration. The first ingot 150a is stored in the storing recess 132a nearest to the turn table 18, the second ingot 150b is stored in the storing recess 132a adjacent to the storing recess 132a storing the first ingot 150a, the third ingot 150c is stored in the storing recess 132a adjacent to the storing recess 132a storing the second ingot 150b, and the fourth ingot 150d is stored in the storing recess 132a adjacent to the storing recess 132a storing the third ingot 150c. However, in the case that the first to fourth ingots 150a to 150d are not required to be distinguished, they will be simply referred to as “ingots 150.”

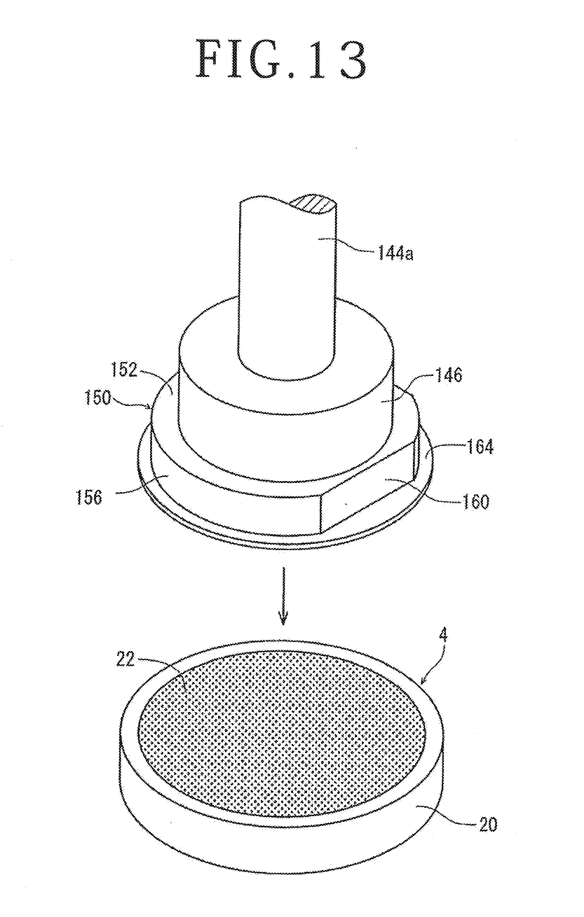

After performing the ingot storing step, an ingot transfer step is performed to transfer each ingot 150 from the ingot storing unit 132 to the holding unit 4 by using the ingot transfer unit 134. In the ingot transfer step, the arm moving mechanism 140 of the ingot transfer unit 134 is first operated to move the arm 138 in the Y direction and then position the suction member 146 directly above the first ingot 150a stored in the ingot storing unit 132. Thereafter, the air cylinder 144 of the ingot transfer unit 134 is operated to lower the suction member 146 and bring the lower surface of the suction member 146 into close contact with the upper surface of the first ingot 150a (e.g., the first surface 152 of the first ingot 150a). Thereafter, the suction unit connected to the suction member 146 is operated to apply a suction force to the lower surface of the suction member 146, thereby holding the upper surface of the first ingot 150a on the lower surface of the suction member 146 under suction. Thereafter, the air cylinder 144 is operated to raise the suction member 146 holding the first ingot 150a. Thereafter, the arm moving mechanism 140 is operated to move the arm 138 in the Y direction and then position the suction member 146 holding the first ingot 150a directly above the chuck table 20 set at the standby position P1. Thereafter, as shown in FIG. 13, the air cylinder 144 is operated to lower the suction member 146 holding the first ingot 150a until the lower surface of the substrate 164 comes into contact with the upper surface of the chuck table 20 set at the standby position P1. Thereafter, the operation of the suction unit connected to the suction member 146 is stopped to thereby remove the suction force applied to the suction member 146, so that the first ingot 150a is placed on the upper surface of the chuck table 20 set at the standby position P1. In this manner, the first ingot 150a can be transferred from the ingot storing unit 132 to the chuck table 20 of the holding unit 4 by using the ingot transfer unit 134.

After performing the ingot transfer step, a holding step is performed to hold each ingot 150 by using the holding unit 4. More specifically, in the holding step, the suction unit connected to the vacuum chuck 22 on which the first ingot 150a has been placed is operated to apply a suction force to the upper surface of the vacuum chuck 22, thereby holding the first ingot 150a on the chuck table 20 under suction.

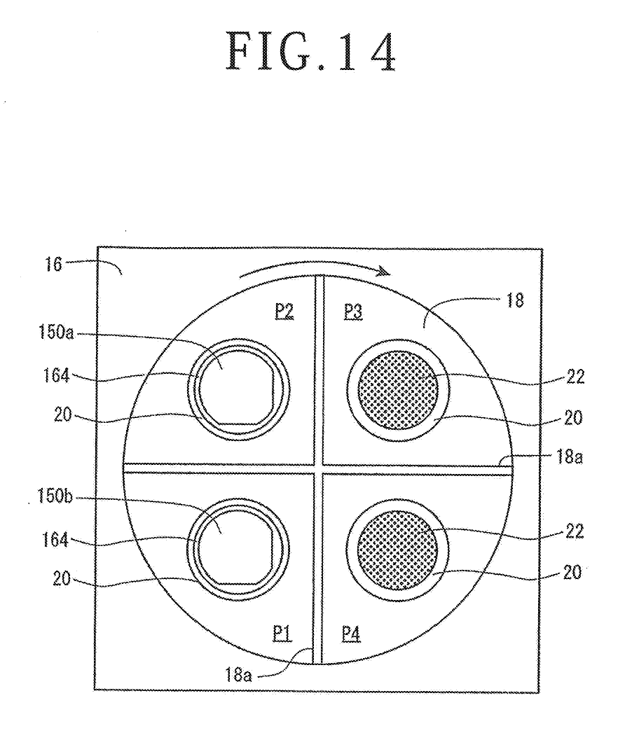

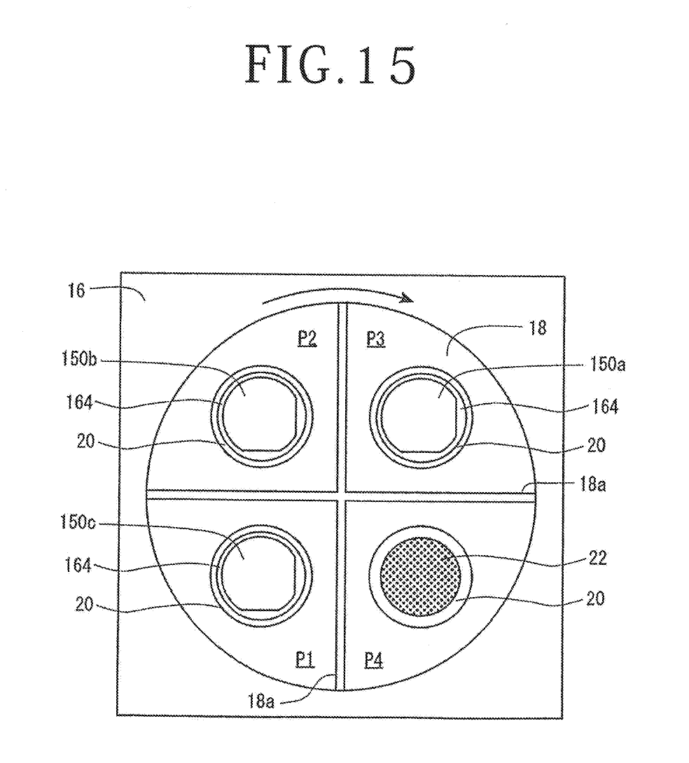

After performing the holding step, the turn table 18 is rotated by the turn table motor by 90 degrees in a clockwise direction as viewed in plan to thereby move the chuck table 20 holding the first ingot 150a from the standby position P1 to the flattening position P2 as shown in FIG. 14. In this stage, the first ingot 150a set at the flattening position P2 is not processed by a flattening step of grinding the upper surface of each ingot 150 held by the holding unit 4 to thereby flatten the upper surface of each ingot 150. That is, usually, the first surface 152 and the second surface 154 of each ingot 150 have already been flattened to such an extent that the surface roughness does not interfere with the incidence of a laser beam in a separation layer forming step to be hereinafter described. Accordingly, the flattening step may not be performed to each ingot 150 first transferred from the ingot storing unit 132 to the chuck table 20 set at the standby position P1 and next moved to the flattening position P2. In concert with the movement of the first ingot 150a from the standby position P1 to the flattening position P2, the ingot transfer step and the holding step are performed for the second ingot 150b stored in the ingot storing unit 132. That is, the ingot transfer unit 134 is operated to transfer the second ingot 150b from the ingot storing unit 132 to the chuck table 20 set at the standby position P1, and the holding unit 4 is next operated to hold the second ingot 150b on the chuck table 20 under suction. In FIG. 14, the orientation of the first ingot 150a set at the flattening position P2 is the same as the orientation of the second ingot 150b set at the standby position P1 for convenience of illustration. However, by the rotation of the turn table 18 and the rotation of each chuck table 20, the orientation of the ingot 150 held on each chuck table 20 becomes arbitrary. This point is similarly applied to FIG. 15 and the other similar figures.

After performing the ingot transfer step and the holding step for the second ingot 150b, the turn table 18 is rotated by the turn table motor by 90 degrees in a clockwise direction as viewed in plan. Accordingly, as shown in FIG. 15, the chuck table 20 holding the first ingot 150a is moved from the flattening position P2 to the laser applying position P3, and the chuck table 20 holding the second ingot 150b is moved from the standby position P1 to the flattening position P2. Thereafter, the first ingot 150a is processed by a separation layer forming step using the laser applying unit 8, and the separation layer forming step is performed in such a manner that the focal point of the laser beam having a transmission wavelength to each ingot 150 is set at a predetermined depth from the upper surface of each ingot 150 held by the holding unit 4, the predetermined depth corresponding to the thickness of the wafer to be produced, and the laser beam is next applied to each ingot 150 to thereby form a separation layer. Thereafter, a production history forming step using the laser applying unit 8 is performed in such a manner that the focal point of the laser beam having a transmission wavelength to each ingot 150 is set inside the wafer to be produced in an area where no devices are to be formed, and the laser beam is next applied to each ingot 150 (the wafer to be produced in the above area) to thereby form a production history inside each ingot 150 (the wafer to be produced in the above area). On the other hand, the second ingot 150b may not be processed by the flattening step because the second ingot 150b is first transferred from the ingot storing unit 132 to the chuck table 20 set at the standby position P1 and next moved to the flattening position P2. In concert with the movement of the second ingot 150b from the standby position P1 to the flattening position P2, the ingot transfer step and the holding step are performed for the third ingot 150c stored in the ingot storing unit 132. That is, the ingot transfer unit 134 is operated to transfer the third ingot 150c from the ingot storing unit 132 to the chuck table 20 set at the standby position P1, and the holding unit 4 is next operated to hold the third ingot 150c on the chuck table 20 under suction.

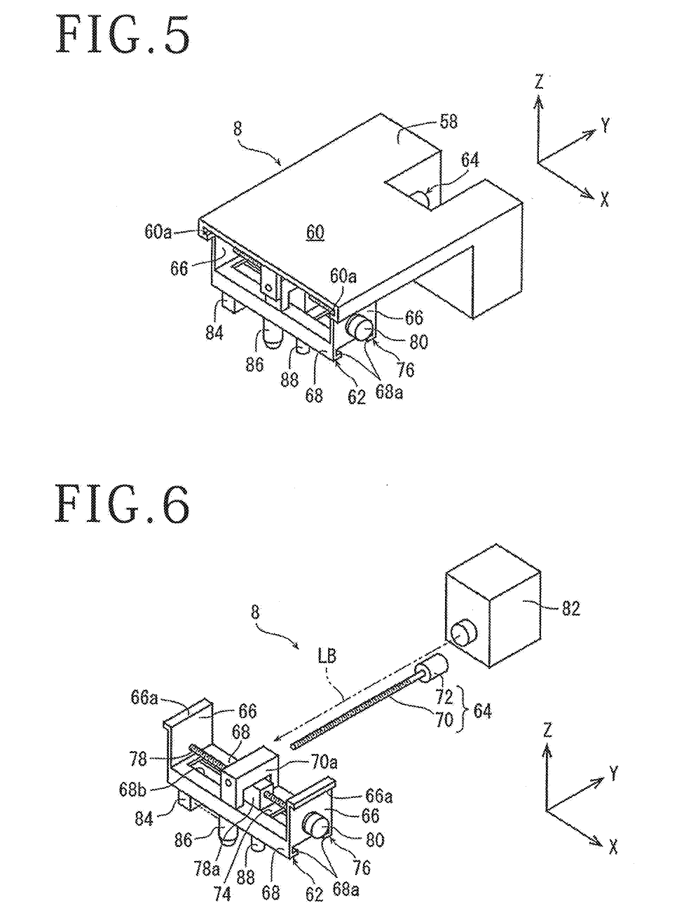

The separation layer forming step using the laser applying unit 8 will now be described. In the separation layer forming step, the X moving mechanism 76 of the laser applying unit 8 (see FIGS. 5 and 6) is operated to move the X movable plate 74 in the X direction and the Y moving mechanism 64 is operated to move the Y movable member 62 in the Y direction, thereby positioning the alignment unit 88 directly above each ingot 150. Thereafter, the alignment unit 88 is operated to image the ingot 150 from the upper side thereof. Thereafter, according to an image of the ingot 150 as obtained by the alignment unit 88, the chuck table 20 is rotated by the chuck table motor, and the X movable plate 74 is moved in the X direction by the X moving mechanism 76. Further, the Y movable member 62 is moved in the Y direction by the Y moving mechanism 64. Accordingly, the orientation of the ingot 150 is adjusted to a predetermined orientation, and the positional relation between the focusing means 86 and the ingot 150 in the XY plane is adjusted.

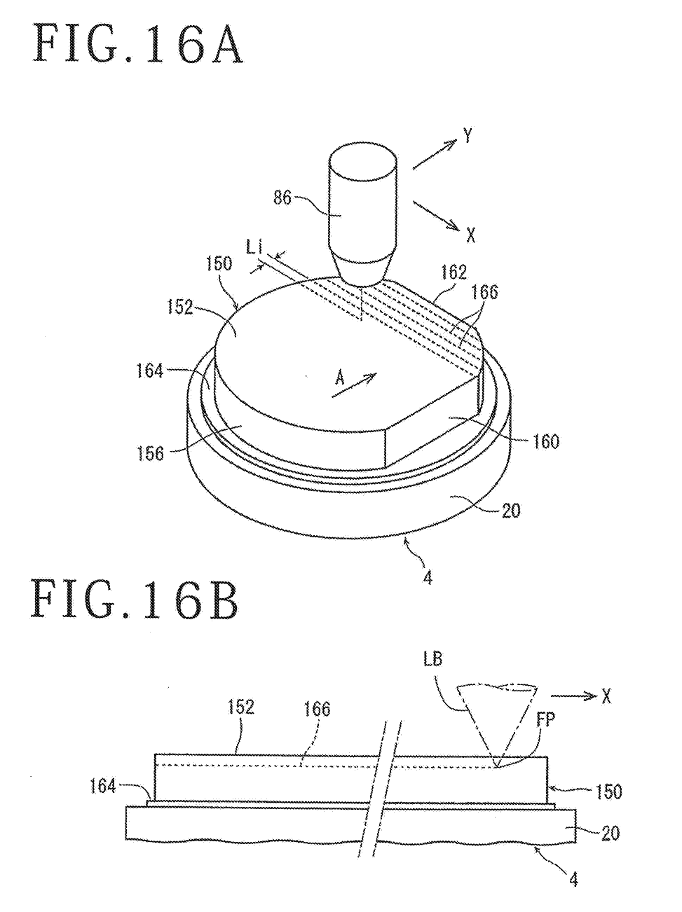

In adjusting the orientation of the ingot 150 to a predetermined orientation, the first orientation flat 160 is made parallel to the Y direction and the second orientation flat 162 is made parallel to the X direction as shown in FIG. 16A. Accordingly, the direction A of formation of the off angle α is made parallel to the Y direction, and the direction perpendicular to the direction A of formation of the off angle α is made parallel to the X direction. Thereafter, the focal position adjusting unit is operated to move the focusing means 86 in the Z direction, thereby setting a focal point FP at a predetermined depth from the upper surface (e.g., the first surface 152) of the ingot 150 as shown in FIG. 16B, and this predetermined depth corresponds to the thickness of the wafer to be produced. Thereafter, a pulsed laser beam LB having a transmission wavelength to the ingot 150 is applied from the focusing means 86 to the ingot 150 as moving the X movable plate 74 by operating the X moving mechanism 76 to thereby move the focal point FP relative to the ingot 150 at a predetermined feed speed in the X direction parallel to the direction perpendicular to the direction A of formation of the off angle α (modified layer forming step).

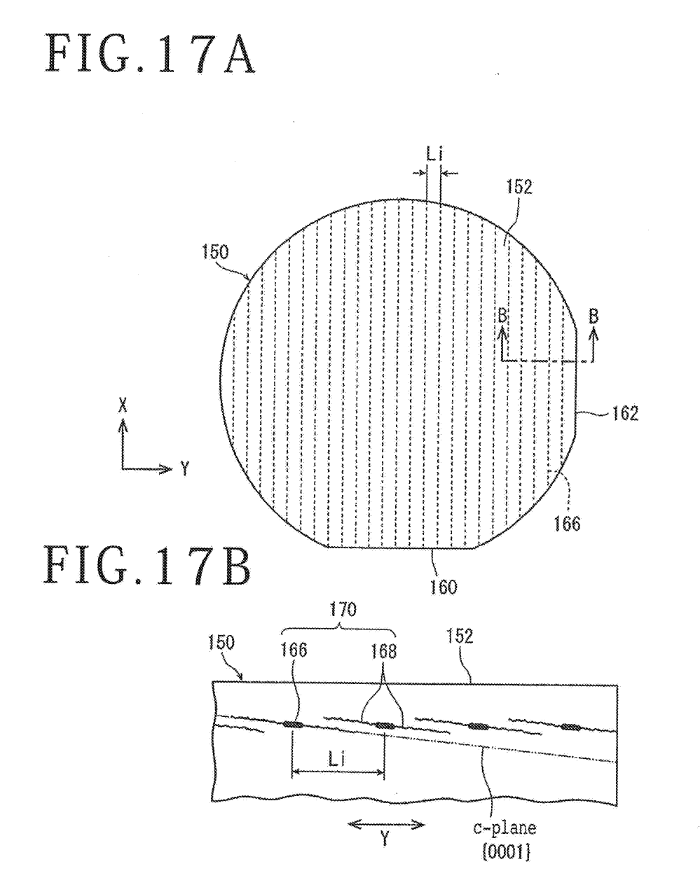

In the modified layer forming step, the pulsed laser beam LB is initially applied to the ingot 150 to thereby decompose SiC into Si and C (carbon). Thereafter, the pulsed laser beam LB is next applied to the ingot 150 and absorbed by C previously produced. Thus, SiC is decomposed into Si and C in a chain reaction manner with the movement of the focal point FP in the X direction to thereby linearly form a modified layer 166 extending in the X direction as shown in FIGS. 17A and 17B. At the same time, cracks 168 are also formed so as to propagate from the modified layer 166 in opposite directions along the c-plane as shown in FIGS. 17A and 17B. In the modified layer forming step, the focal point FP is fed in the X direction relative to the ingot 150 so that the adjacent spots of the pulsed laser beam LB applied to the ingot 150 are overlapped with each other at the depth where the modified layer 166 is formed (i.e., a plurality of circular modified portions are overlapped with each other to form the linear modified layer 166). Accordingly, the pulsed laser beam LB is applied again to the modified layer 166 (to the circular modified portion previously formed) where SiC has been decomposed into Si and C. In order to ensure that the adjacent spots of the pulsed laser beam LB are overlapped with each other in the modified layer forming step, the relation of G=(V/F)−D<0 must hold, where F is the repetition frequency of the pulsed laser beam LB, V is the feed speed of the focal point FP, and D is the diameter of each spot. Further, the overlap rate of the adjacent spots is defined as |G|/D.

The separation layer forming step will further be described with reference to FIGS. 16A to 17B. After performing the modified layer forming step along a line in the X direction, an indexing step is performed in such a manner that the Y movable member 62 is moved by the Y moving mechanism 64 to thereby move the focal point FP relative to the ingot 150 by a predetermined index amount Li in the Y direction parallel to the direction A of formation of the off angle α. Thereafter, the modified layer forming step and the indexing step are alternately repeated plural times to thereby form a plurality of linear modified layers 166 spaced from each other by the predetermined index amount Li in the direction A of formation of the off angle α (in the Y direction). Each linear modified layer 166 extends in the direction perpendicular to the direction A of formation of the off angle α (in the X direction) as shown in FIG. 17A. Furthermore, the cracks 168 propagating from each linear modified layer 166 and the cracks 168 propagating from its adjacent linear modified layer 166 are overlapped with each other in the direction of formation of the off angle α (in the Y direction) as shown in FIG. 17B. Accordingly, a separation layer 170 for separating the wafer from the ingot 150 can be formed inside the ingot 150 at a predetermined depth from the upper surface of the ingot 150, the predetermined depth corresponding to the thickness of the wafer to be produced. The separation layer 170 is composed of the plural modified layers 166 and the cracks 168 propagating therefrom as shown in FIG. 17B. For example, the separation layer forming step for forming the separation layer 170 inside the ingot 150 may be performed under the following processing conditions.

Wavelength of the pulsed laser beam: 1064 nm

Repetition frequency: 80 kHz

Average power: 3.2 W

Pulse width: 4 ns

Diameter of the focal point: 3 μm

Numerical aperture (NA) of the focusing lens: 0.43

Z position of the focal point: 300 μm in depth from the upper surface of the ingot

Feed speed of the focal point: 120 to 260 mm/second

Index amount: 250 to 400 μm

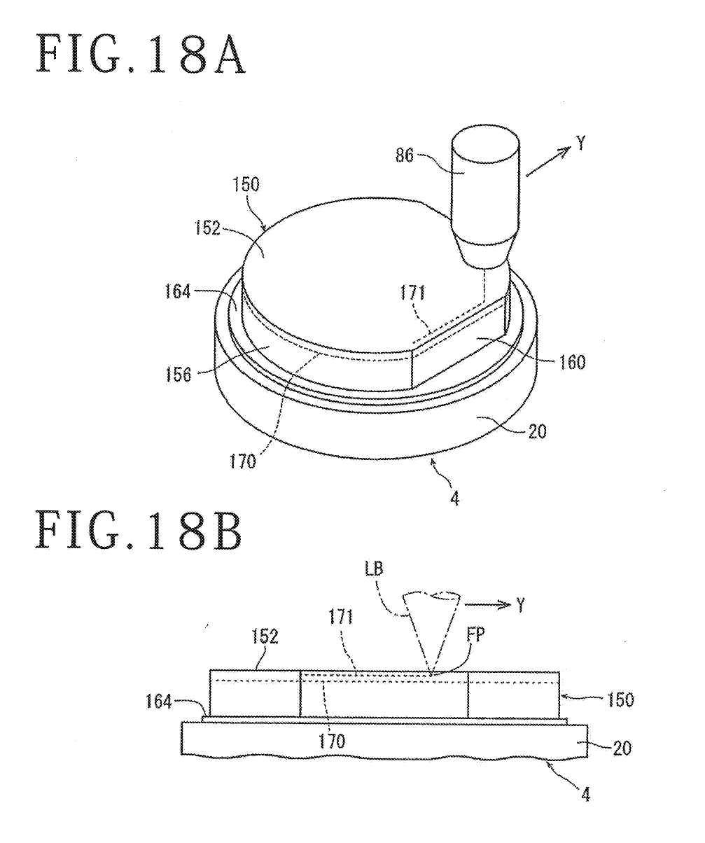

The production history forming step using the laser applying unit 8 will now be described. In the production history forming step, according to the image of the ingot 150 as obtained by the alignment unit 88 in the separation layer forming step, the chuck table 20 is rotated by the chuck table motor, and the X movable plate 74 is moved in the X direction by the X moving mechanism 76. Further, the Y movable member 62 is moved in the Y direction by the Y moving mechanism 64. Accordingly, the focusing means 86 is positioned above a predetermined area of the wafer to be produced where no devices are to be formed. For example, as shown in FIG. 18A, the focusing means 86 is positioned above a part of a peripheral marginal area of the wafer to be produced where no devices are to be formed, and this part of the peripheral marginal area extends along the first orientation flat 160. Thereafter, the focal position adjusting unit is operated to move the focusing means 86 in the Z direction, thereby setting the focal point FP inside the wafer to be produced at a given depth from the upper surface (the first surface 152) of the ingot 150 as shown in FIG. 18B. Thereafter, a pulsed laser beam LB having a transmission wavelength to the ingot 150 is applied from the focusing means 86 to the ingot 150 as relatively suitably moving the ingot 150 and the focal point FP. As a result, a production history 171 can be formed by the pulsed laser beam LB inside the wafer to be produced, and the production history 171 may be configured in the form of a bar code. Preferably, the production history 171 to be formed in the production history forming step includes any one of the lot number of the ingot 150, the serial number of the wafer to be produced from the ingot 150, the date of production of the wafer, the production plant where the wafer is to be produced, and the kind of the wafer producing apparatus contributing to the production of the wafer.

While the production history 171 is formed along the first orientation flat 160 in this preferred embodiment, the area of the wafer to be produced where no devices are to be formed is not limited to this area. For example, the production history 171 may be formed along the second orientation flat 162 or along the arcuate edge of the ingot 150. In relatively moving the ingot 150 and the focal point FP in the production history forming step, the X moving mechanism 76, the Y moving mechanism 64, and the chuck table motor may be operated to relatively move the ingot 150 and the focal point FP in the X direction, the Y direction, and the circumferential direction of the ingot 150. The depth of the production history 171 to be formed inside the wafer to be produced is set in such a manner that the production history 171 is vertically spaced a given distance from the separation layer 170 formed in the separation layer forming step. With this setting, the production history 171 is not removed in grinding the separation surface of the wafer to flatten the same after separating the wafer from the ingot 150. Further, the power of the pulsed laser beam LB to be applied to the ingot 150 in the production history forming step may be made different from the power of the pulsed laser beam LB to be applied to the ingot 150 in the separation layer forming step, by using the attenuator to suitably adjust the power of the pulsed laser beam LB oscillated from the laser oscillator 82. For example, the production history forming step may be performed under the following processing conditions.

Wavelength of the pulsed laser beam: 1064 nm

Repetition frequency: 80 kHz

Average power: 1.0 W

Pulse width: 4 ns

Diameter of the focal point: 3 μm

Numerical aperture (NA) of the focusing lens: 0.43

Z position of the focal point: 100 μm in depth from the upper surface of the ingot

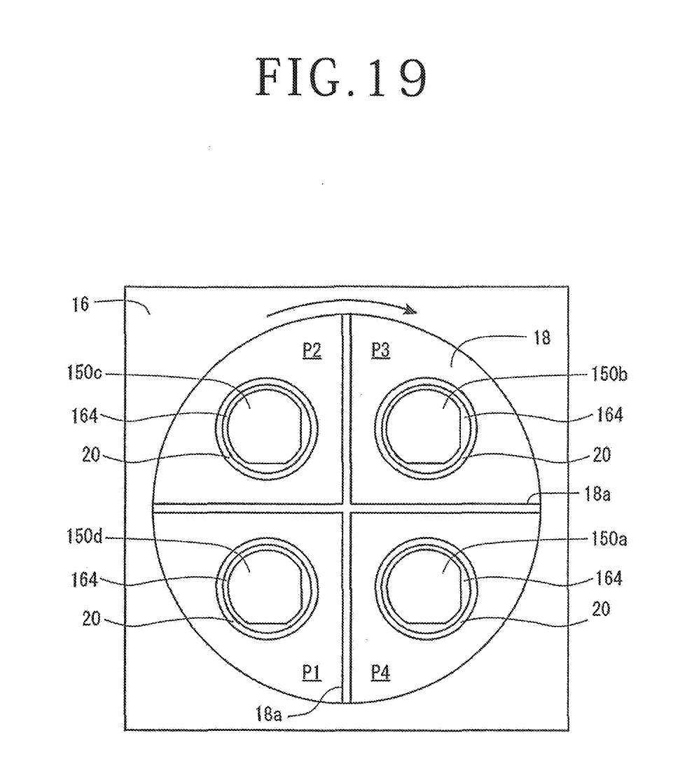

After performing the separation layer forming step and the production history forming step for the first ingot 150a and performing the ingot transfer step and the holding step for the third ingot 150c, the turn table 18 is rotated by the turn table motor by 90 degrees in a clockwise direction as viewed in plan. Accordingly, as shown in FIG. 19, the chuck table 20 holding the first ingot 150a in which the separation layer 170 and the production history 171 have been formed is moved from the laser applying position P3 to the wafer separating position P4. At the same time, the chuck table 20 holding the second ingot 150b is moved from the flattening position P2 to the laser applying position P3, and the chuck table 20 holding the third ingot 150c is moved from the standby position P1 to the flattening position P2. At the wafer separating position P4, the first ingot 150a is processed by a wafer producing step using the wafer separating unit 10. The wafer producing step is performed in such a manner that the wafer to be produced is separated from each ingot 150 along the separation layer 170. Further, the second ingot 150b is processed by the separating layer forming step and the production history forming step using the laser applying unit 8. On the other hand, the third ingot 150c may not be processed by the flattening step because the third ingot 150c is first transferred from the ingot storing unit 132 to the chuck table 20 set at the standby position P1 and next moved to the flattening position P2. In concert with the movement of the third ingot 150c from the standby position P1 to the flattening position P2, the ingot transfer step and the holding step are performed for the fourth ingot 150d stored in the ingot storing unit 132. That is, the ingot transfer unit 134 is operated to transfer the fourth ingot 150d from the ingot storing unit 132 to the chuck table 20 set at the standby position P1, and the holding unit 4 is next operated to hold the fourth ingot 150d on the chuck table 20 under suction.

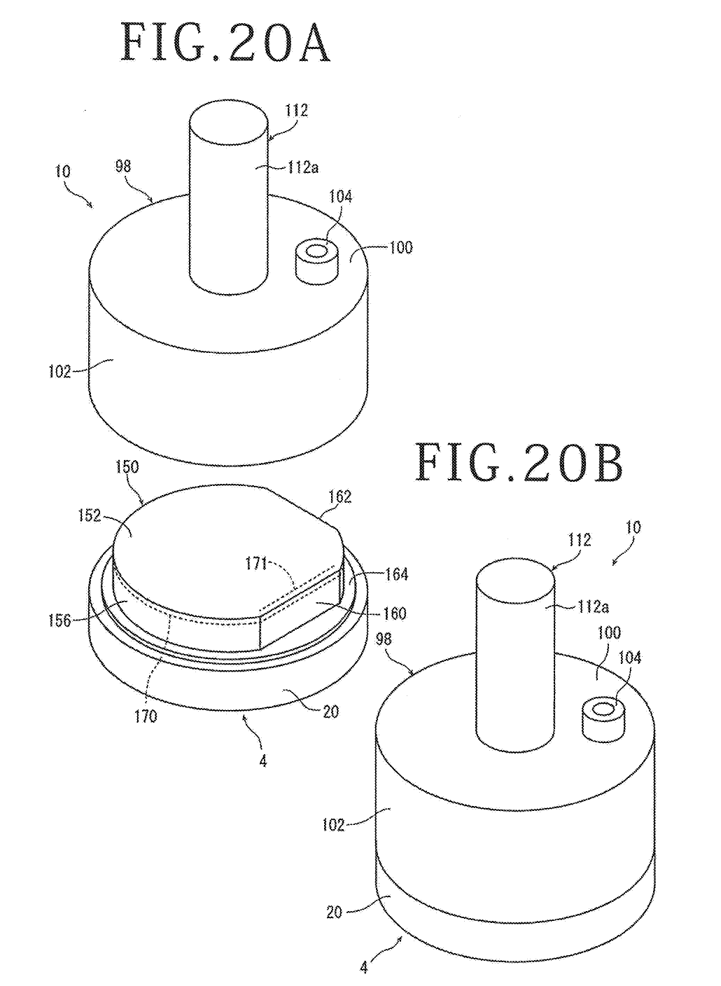

The wafer producing step using the wafer separating unit 10 will now be described with reference to FIGS. 9, 20A, 20B, and 21. In the wafer producing step, the arm moving mechanism 94 is operated to lower the arm 92 and bring the lower end of the side wall 102 of the liquid tank 98 into close contact with the upper surface of the chuck table 20 holding the ingot 150 in which the separation layer 170 and the production history 171 have been formed as shown in FIGS. 20A and 20B. Thereafter, as shown in FIG. 9, the air cylinder 112 of the wafer separating unit 10 is operated to lower the piston rod 112b and bring the lower surface of the suction member 116 into close contact with the upper surface of the ingot 150. Thereafter, the suction unit connected to the suction member 116 is operated to apply a suction force to the lower surface of the suction member 116, so that the upper surface of the ingot 150 is held by the lower surface of the suction member 116 under suction. Thereafter, the liquid supply unit connected to the liquid inlet portion 104 is operated to supply the liquid 110 (e.g., water) from the liquid inlet portion 104 into the liquid storing space 108 until the ultrasonic vibration generating member 114 is immersed in the liquid 110.

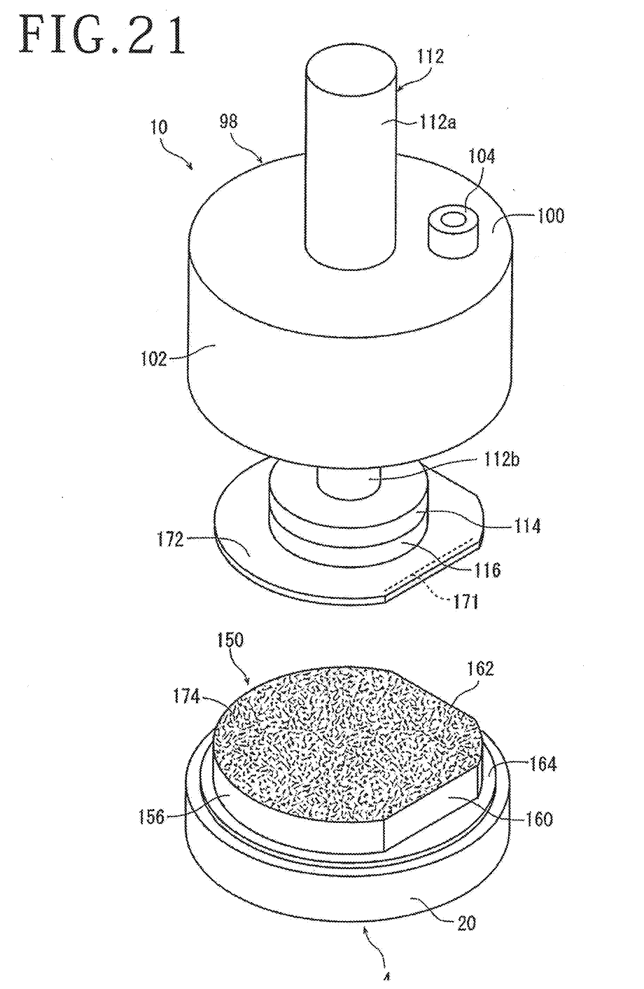

Thereafter, the ultrasonic vibration generating member 114 is operated to apply ultrasonic vibration to the ingot 150, so that a wafer 172 to be produced can be separated from the ingot 150 along the separation layer 170 as a separation start point, thereby producing the wafer 172 from the ingot 150. Thereafter, the arm moving mechanism 94 is operated to raise the arm 92, thereby separating the liquid tank 98 from the chuck table 20, so that the liquid 110 is discharged from the liquid storing space 108. The liquid 110 discharged from the liquid storing space 108 is drained through a drain opening 16a (see FIG. 2) to the outside of the wafer producing apparatus 2, and the drain opening 16a is formed in the turn table accommodating portion 16 of the base 14 at a position adjacent to the wafer separating unit 10. Thereafter, as shown in FIG. 21, the air cylinder 112 is operated to lower the piston rod 112b until the wafer 172 produced from the ingot 150 projects downward from the lower end of the side wall 102 of the liquid tank 98. As shown in FIG. 21, after separating the wafer 172 from the ingot 150, the upper surface of the ingot 150 becomes a rough separation surface 174. The height of the roughness of the rough separation surface 174 is approximately 100 μm, for example.

After performing the wafer producing step for the first ingot 150a, a wafer transfer step is performed by using the wafer transfer unit 118 in such a manner that the wafer 172 produced from the first ingot 150a is transferred from the wafer separating unit 10 to the wafer storing unit 12. In the wafer transfer step, the first arm 124 is operated by the first motor 122 of the wafer transfer unit 118, and the second arm 128 is operated by the second motor 126 of the wafer transfer unit 118 to thereby position the suction member 130 of the wafer transfer unit 118 directly below the wafer 172 held by the suction member 116 of the wafer separating unit 10 after separating the wafer 172 from the first ingot 150a. Thereafter, the elevating unit 120 of the wafer transfer unit 118 is operated to bring the upper surface of the suction member 130 of the wafer transfer unit 118 into close contact with the lower surface of the wafer 172. Thereafter, the operation of the suction unit connected to the suction member 116 of the wafer separating unit 10 is stopped to remove the suction force applied to the suction member 116. Thereafter, the suction unit connected to the suction member 130 of the wafer transfer unit 118 is operated to apply a suction force to the upper surface of the suction member 130, thereby holding the lower surface of the wafer 172 on the upper surface of the suction member 130 under suction. Thusly, the wafer 172 is received by the wafer transfer unit 118 from the wafer separating unit 10. Thereafter, the elevating unit 120, the first motor 122, and the second motor 126 are operated to move the first arm 124 and the second arm 128, thereby transferring the wafer 172 held by the suction member 130 from the wafer separating unit 10 to the wafer storing unit 12, and then storing the wafer 172 into the wafer storing unit 12. In this preferred embodiment, the wafer 172 produced from the first ingot 150a is stored into the first cassette 131a, so as to easily identify whether the wafer 172 has been produced from the first ingot 150a.

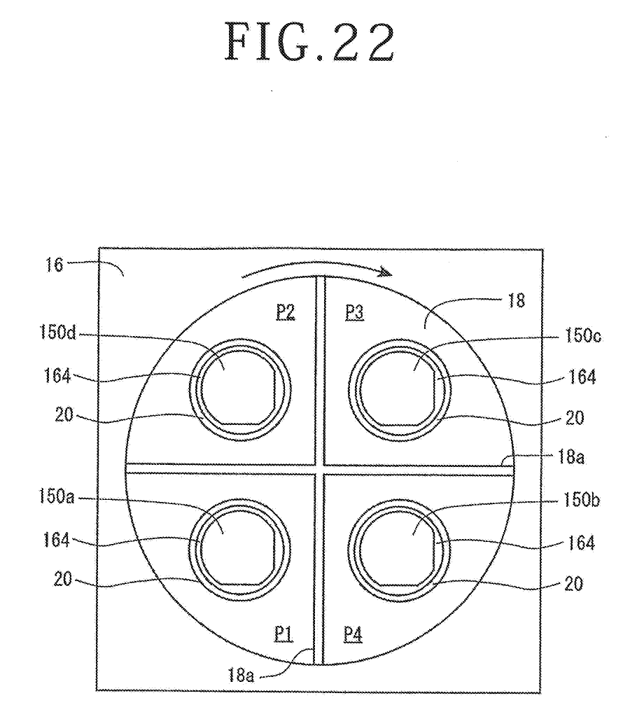

After performing the wafer producing step for the first ingot 150a, performing the wafer transfer step for the wafer 172 produced from the first ingot 150a, performing the separation layer forming step and the production history forming step for the second ingot 150b, and performing the ingot transfer step and the holding step for the fourth ingot 150d, the turn table 18 is rotated by the turn table motor by 90 degrees in a clockwise direction as viewed in plan. Accordingly, as shown in FIG. 22, the chuck table 20 holding the first ingot 150a is moved from the wafer separating position P4 to the standby position P1, the chuck table 20 holding the second ingot 150b is moved from the laser applying position P3 to the wafer separating position P4, the chuck table 20 holding the third ingot 150c is moved from the flattening position P2 to the laser applying position P3, and the chuck table 20 holding the fourth ingot 150d is moved from the standby position P1 to the flattening position P2. Thereafter, the wafer producing step is performed for the second ingot 150b by using the wafer separating unit 10, and the wafer transfer step is performed for the wafer 172 produced from the second ingot 150b, by using the wafer transfer unit 118. In this preferred embodiment, the wafer 172 produced from the second ingot 150b is stored into the second cassette 131b. Further, the separation layer forming step and the production history forming step are performed for the third ingot 150c by using the laser applying unit 8. On the other hand, the flattening step may not be performed for the fourth ingot 150d because the fourth ingot 150d is first transferred from the ingot storing unit 132 to the chuck table 20 set at the standby position P1 and next moved to the flattening position P2. The first ingot 150a moved from the wafer separating position P4 to the standby position P1 waits at the standby position P1 until the turn table 18 is next rotated.

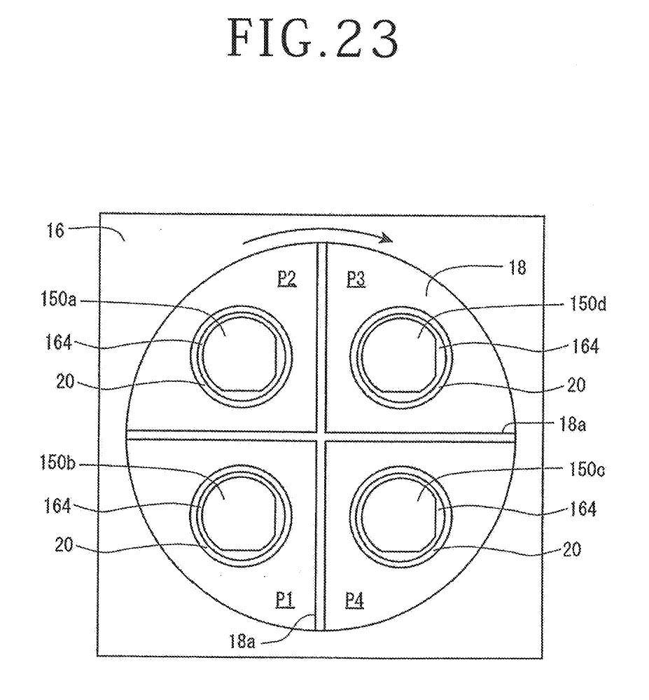

After performing the wafer producing step for the second ingot 150b, performing the wafer transfer step for the wafer 172 produced from the second ingot 150b, and performing the separation layer forming step and the production history forming step for the third ingot 150c, the turn table 18 is rotated by the turn table motor by 90 degrees in a clockwise direction as viewed in plan. Accordingly, as shown in FIG. 23, the chuck table 20 holding the first ingot 150a is moved from the standby position P1 to the flattening position P2, the chuck table 20 holding the second ingot 150b is moved from the wafer separating position P4 to the standby position P1, the chuck table 20 holding the third ingot 150c is moved from the laser applying position P3 to the wafer separating position P4, and the chuck table 20 holding the fourth ingot 150d is moved from the flattening position P2 to the laser applying position P3. The flattening step using the flattening unit 6 is performed for the first ingot 150a in such a manner that the upper surface of the ingot 150 is ground to be flattened. The wafer producing step is performed for the third ingot 150c by using the wafer separating unit 10. The wafer transfer step using the wafer transfer unit 118 is performed for the wafer 172 produced from the third ingot 150c. In this preferred embodiment, the wafer 172 produced from the third ingot 150c is stored into the third cassette 131c. The separation layer forming step and the production history forming step using the laser applying unit 8 are performed for the fourth ingot 150d. The second ingot 150b moved from the wafer separating position P4 to the standby position P1 waits at the standby position P1 until the turn table 18 is next rotated.

The flattening step using the flattening unit 6 will now be described with reference to FIGS. 2 and 3. In the flattening step, the chuck table 20 holding the ingot 150 from which the wafer 172 has been separated is rotated by the chuck table motor at a predetermined speed (e.g., 300 rpm) in a counterclockwise direction as viewed in plan. Further, the spindle 40 of the flattening unit 6 is rotated by the motor 36 at a predetermined speed (e.g., 6000 rpm) in a counterclockwise direction as viewed in plan. Thereafter, the Z moving mechanism 28 of the flattening unit 6 is operated to lower the Z movable plate 26 and bring the abrasive members 48 into contact with the separation surface 174 of the ingot 150. After the abrasive members 48 come into contact with the separation surface 174, the Z movable plate 26 is further lowered by the Z moving mechanism 28 at a predetermined feed speed (e.g., 1.0 μm/second). Accordingly, the separation surface 174 of the ingot 150 from which the wafer 172 has been separated is ground by the abrasive members 48 and thereby flattened to such an extent that the surface roughness of the upper surface of the ingot 150 does not interfere with the incidence of the pulsed laser beam LB in the separation layer forming step. In grinding the separation surface 174 of the ingot 150 to flatten the same, a thickness gauge (not shown) may be used to measure the thickness of the ingot 150. In this case, the thickness gauge is brought into contact with the separation surface 174 of the ingot 150, and it is detected that the thickness of the ingot 150 measured by the thickness gauge has been reduced by a predetermined amount (e.g., 100 μm corresponding to the height of the roughness of the separation surface 174). As a result, it is possible to detect that the upper surface of the ingot 150 has been suitably flattened. Further, in the flattening step, a grinding water is supplied from a grinding water supply unit (not shown) to a grinding area in grinding the separation surface 174 of the ingot 150. The grinding water supplied to the grinding area is drained through a drain opening 16b (see FIG. 2) to the outside of the wafer producing apparatus 2. The drain opening 16b is formed in the turn table accommodating portion 16 of the base 14 at a position adjacent to the flattening unit 6.

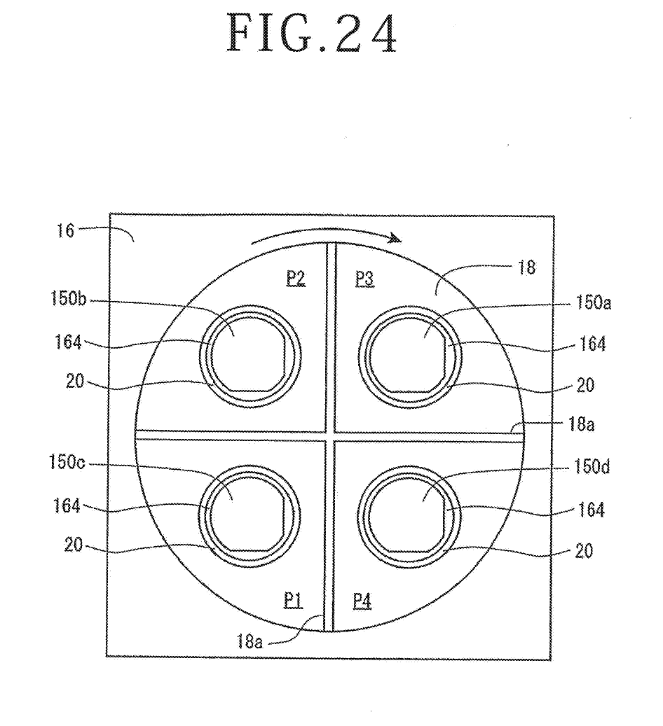

After performing the flattening step for the first ingot 150a, performing the wafer producing step for the third ingot 150c, performing the wafer transfer step for the wafer 172 produced from the third ingot 150c, and performing the separation layer forming step and the production history forming step for the fourth ingot 150d, the turn table 18 is rotated by the turn table motor by 90 degrees in a clockwise direction as viewed in plan. Accordingly, as shown in FIG. 24, the chuck table 20 holding the first ingot 150a is moved from the flattening position P2 to the laser applying position P3, the chuck table 20 holding the second ingot 150b is moved from the standby position P1 to the flattening position P2, the chuck table 20 holding the third ingot 150c is moved from the wafer separating position P4 to the standby position P1, and the chuck table 20 holding the fourth ingot 150d is moved from the laser applying position P3 to the wafer separating position P4. Just after performing the flattening step for the first ingot 150a, the cleaning unit 50 is operated to clean the first ingot 150a in the following manner. The cleaning water 55 is discharged obliquely downward toward the first ingot 150a from each nozzle hole of the first cleaning portion 54 to thereby remove a grinding dust from the first ingot 150a. Thereafter, the dry air 57 is discharged downward from each nozzle hole of the second cleaning portion 56 to thereby remove the cleaning water 55 from the first ingot 150a. Thus, the first ingot 150a processed by the flattening unit 6 is cleaned and dried by the cleaning unit 50. After cleaning the first ingot 150a, the separation layer forming step and the production history forming step are performed for the first ingot 150b by using the laser applying unit 8. Further, the flattening step is performed for the second ingot 150b by using the flattening unit 6. Further, the wafer producing step is performed for the fourth ingot 150d by using the wafer separating unit 10, and the wafer transfer step is performed for the wafer 172 produced from the fourth ingot 150d, by using the wafer transfer unit 118. In this preferred embodiment, the wafer 172 produced from the fourth ingot 150d is stored into the fourth cassette 131d. Further, the third ingot 150c moved from the wafer separating position P4 to the standby position P1 waits at the standby position P1 until the turn table 18 is next rotated.

Thereafter, every time the turn table 18 is rotated by the turn table motor by 90 degrees in a clockwise direction as viewed in plan, each chuck table 20 is sequentially set at the standby position P1, the flattening position P2, the laser applying position P3, and the wafer separating position P4. Thereafter, the flattening step, the separation layer forming step, the production history forming step, and the wafer producing step are repeatedly performed for each ingot 150 held on each chuck table 20. Further, the wafer transfer step is performed for each wafer 172 separated by the wafer separating unit 10. Accordingly, an obtainable number of wafers 172 are produced from each ingot 150, and the wafers 172 thus produced are stored into the wafer storing unit 12.

After producing an obtainable number of wafers 172 from each ingot 150, a substrate recovering step may be performed to recover the substrate 164 on which a part of the ingot 150 is slightly left. A suitable recovery container 176 (see FIGS. 1 and 2) for recovering the substrate 164 is located on the upper surface of the base 14 at the front end portion thereof in the vicinity of the ingot transfer unit 134. The substrate 164 is transferred to the substrate recovery container 176 by the ingot transfer unit 134. More specifically, in the substrate recovering step, the arm moving mechanism 140 of the ingot transfer unit 134 is operated to move the arm 138 in the Y direction and thereby position the suction member 146 directly above the substrate 164 set at the standby position P1. Thereafter, the air cylinder 144 of the ingot transfer unit 134 is operated to lower the suction member 146 and bring the lower surface of the suction member 146 into close contact with the upper surface of the substrate 164. Thereafter, the suction unit connected to the suction member 146 is operated to apply a suction force to the lower surface of the suction member 146, thereby holding the upper surface of the substrate 164 on the lower surface of the suction member 146 under suction. Thereafter, the air cylinder 144 is operated to raise the suction member 146 holding the substrate 164. Thereafter, the arm moving mechanism 140 is operated to move the arm 138 in the Y direction and thereby position the suction member 146 directly above the recovery container 176. Thereafter, the operation of the suction unit connected to the suction member 146 is stopped to remove the suction force applied to the suction member 146, thereby storing the substrate 164 into the recovery container 176. Thereafter, the turn table 18 is rotated by the turn table motor to sequentially move the substrate 164 to the standby position P1. Thereafter, the above substrate recovering step may be similarly performed for each substrate 164. Thus, all of the substrates 164 may be recovered into the recovery container 176.

In the above preferred embodiment described above, the wafer producing apparatus 2 includes: the holding unit 4 for holding the ingot 150; the flattening unit 6 for grinding the upper surface of the ingot 150 to thereby flatten the same; the laser applying unit 8 functioning both as the separation layer forming unit for forming the separation layer 170 inside the ingot 150 at a predetermined depth from the upper surface of the ingot 150, the predetermined depth corresponding to the thickness of the wafer 172 to be produced and as the production history forming unit for forming the production history 171 inside the wafer 172 to be produced in an area where no devices are to be formed; the wafer separating unit 10 for holding the upper surface of the ingot 150 to separate the wafer 172 from the ingot 150 along the separation layer 170; and the wafer storing unit 12 for storing the wafer 172 separated from the ingot 150. Further, the wafer producing method using the wafer producing apparatus 2 includes: the flattening step of flattening the upper surface of the ingot 150; the separation layer forming step of forming the separation layer 170 inside the ingot 150 at a predetermined depth from the upper surface of the ingot 150, the predetermined depth corresponding to the thickness of the wafer 172 to be produced; the production history forming step of forming the production history 171 inside the wafer 172 to be produced in the area where no devices are to be formed; and the wafer producing step of separating the wafer 172 from the ingot 150 along the separation layer 170 as a separation start point to thereby produce the wafer 172 from the ingot 150. By performing this wafer producing method, the production history 171 of the wafer 172 separated from the ingot 150 is formed inside the wafer 172 to be produced. Accordingly, in a subsequent step of forming devices on the wafer 172, the production history 171 of the wafer 172 can be checked. In the case that a defect in any device formed on the wafer 172 is found, the cause of this defect in the device can be investigated by referring to the production history 171 of the wafer 172. Accordingly, the recurrence of the defect can be prevented.

The wafer producing method according to the present invention essentially includes the production history forming step of setting the focal point of a laser beam having a transmission wavelength to the ingot inside the wafer to be produced in an area where no devices are to be formed, and next applying the laser beam to the ingot to thereby form a production history for the wafer. Accordingly, the wafer producing method according to the present invention is not limited to the wafer producing method using the wafer producing apparatus 2 mentioned above. For example, the wafer producing method according to the present invention is applicable also to the case of producing a wafer from an ingot by using an inner saw or a wire saw. In the case of producing a wafer from an ingot by using an inner saw, a production history can be formed in the wafer to be produced, by applying the laser beam to the ingot. In the case of producing a wafer from an ingot by using a wire saw, a production history can be formed in the wafer produced from the ingot, by applying the laser beam to the wafer.

In the separation layer forming step in the above preferred embodiment, the focal point FP is moved relative to the ingot 150 in the direction perpendicular to the direction A of formation of the off angle α in the modified layer forming step, and the focal point FP is moved relative to the ingot 150 in the direction A of formation of the off angle α in the indexing step. As a modification, the direction of movement of the focal point FP relative to the ingot 150 in the modified layer forming step may not be the direction perpendicular to the direction A of formation of the off angle α, and the direction of movement of the focal point FP relative to the ingot 150 in the indexing step may not be the direction A of formation of the off angle α. Further, the wafer producing apparatus 2 may include a wafer grinding unit for grinding a separation surface of the wafer 172 separated from the ingot 150 by the wafer separating unit 10.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A wafer producing method for producing a wafer from a semiconductor ingot, said wafer producing method comprising a production history forming step of setting a focal point of a laser beam having a transmission wavelength to said ingot inside said wafer to be produced in an area where no devices are to be formed, and next applying said laser beam to said ingot to thereby form a production history for said wafer.

2. The wafer producing method according to claim 1, wherein said production history to be formed in said production history forming step includes any one of a lot number of said ingot, a serial number of said wafer to be produced, a date of production of said wafer, a production plant where said wafer is to be produced, and a kind of a wafer production apparatus contributing to the production of said wafer.

3. A wafer producing method for producing a wafer from a semiconductor ingot, said wafer producing method comprising:
a flattening step of flattening an upper surface of said ingot;
a separation layer forming step of setting a focal point of a first laser beam having a transmission wavelength to said ingot inside said ingot at a predetermined depth from the upper surface of said ingot after performing said flattening step, said predetermined depth corresponding to a thickness of said wafer to be produced, and next applying said first laser beam to said ingot to thereby form a separation layer for separating said wafer from said ingot;
a production history forming step of setting the focal point of a second laser beam having a transmission wavelength to said ingot inside said wafer to be produced in an area where no devices are to be formed, and next applying said second laser beam to said ingot to thereby form a production history for said wafer inside said ingot; and
a wafer producing step of separating said wafer from said ingot along said separation layer as a separation start point after performing said separation layer forming step and said production history forming step, thereby producing said wafer from said ingot.

4. The wafer producing method according to claim 3, wherein said production history to be formed in said production history forming step includes any one of a lot number of said ingot, a serial number of said wafer to be produced, a date of production of said wafer, a production plant where said wafer is to be produced, and a kind of a wafer producing apparatus contributing to the production of said wafer.

5. The wafer producing method according to claim 3, wherein said semiconductor ingot comprises a single crystal SiC ingot having a first surface, a second surface opposite to said first surface, a c-axis extending from said first surface to said second surface, and a c-plane perpendicular to said c-axis, said c-axis being inclined by an off angle with respect to a normal to said first surface, said off angle being formed between said c-plane and said first surface;
said separation layer forming step comprising:
a modified layer forming step of setting the focal point of a pulsed laser beam having a transmission wavelength to said SiC ingot inside said SiC ingot at a predetermined depth from said first surface, said predetermined depth corresponding to the thickness of said wafer to be produced, and next applying said pulsed laser beam to said SiC ingot as relatively moving said SiC ingot and said focal point in a first direction perpendicular to a second direction where said off angle is formed, thereby forming a linear modified layer inside said SiC ingot at said predetermined depth so as to extend in said first direction and cracks extending from said modified layer in opposite directions along said c-plane, said modified layer being formed in such a manner that SiC is decomposed into Si and C by said pulsed laser beam first applied, and said pulsed laser beam next applied is absorbed by C previously produced to continue the decomposition of SiC into Si and C in a chain reaction manner with the relative movement of said SiC ingot and said focal point in said first direction; and
an indexing step of relatively moving said SiC ingot and said focal point in said second direction by a predetermined index amount;
said modified layer forming step and said indexing step being alternately repeated plural times to thereby form said separation layer inside said SiC ingot in the condition where a plurality of linear modified layers are arranged at given intervals in said second direction so as to be connected through said cracks.

6. A wafer producing apparatus for producing a wafer from a semiconductor ingot, said wafer producing apparatus comprising:
a chuck table for holding said ingot;
a flattening unit for grinding an upper surface of said ingot held on said chuck table to thereby flatten the upper surface of said ingot;
a separation layer forming unit for setting a focal point of a first laser beam having a transmission wavelength to said ingot inside said ingot at a predetermined depth from the upper surface of said ingot, said predetermined depth corresponding to a thickness of said wafer to be produced, and next applying said first laser beam to said ingot to thereby form a separation layer for separating said wafer from said ingot;
a production history forming unit for setting a focal point of a second laser beam having a transmission wavelength to said ingot inside said wafer to be produced in an area where no devices are to be formed, and next applying said second laser beam to said ingot to thereby form a production history for said wafer inside said ingot;
a wafer separating unit for separating said wafer having said production history from said ingot along said separation layer as a separation start point to thereby produce said wafer from said ingot; and
a wafer storing unit for storing said wafer separated from said ingot by said wafer separating unit.
